(19) United States
(12) Patent Application Publication
(10) Pub. No.: US 2025/0268034 A1
(43) Pub. Date: Aug. 21, 2025

(54) DISPLAY DEVICE AND ELECTRONIC DEVICE INCLUDING THE SAME

(71) Applicant: Samsung Display Co., LTD., Yongin-si (KR)

(72) Inventors: Hyun Ae PARK, Yongin-si (KR); Tae Hoon KWON, Yongin-si (KR)

(21) Appl. No.: 18/936,578

(22) Filed: Nov. 4, 2024

(30) Foreign Application Priority Data
Feb. 19, 2024 (KR) 10-2024-0023717

(51) Int. Cl. H10K 59/131; G09G 3/3233; H10K 59/121

(52) U.S. Cl. CPC H10K 59/131; G09G 3/3233; H10K 59/1213; H10K 59/1216; G09G 2300/0852; G09G 2300/0861; G09G 2330/021

(57) ABSTRACT

According to embodiments of the disclosure, a display device includes a first sub-pixel including a first pixel circuit, a second sub-pixel including a second pixel circuit, and extending in a first direction from the first sub-pixel, a (1_2)-th power line overlapping the first pixel circuit, and extending in a second direction crossing the first direction, a (2_2)-th power line overlapping the second pixel circuit, and extending in the second direction, a (1_1)-th power line connecting the (1_2)-th power line and the second sub-pixel, and extending in the first direction, and a (2_1)-th power line connecting the (2_2)-th power line and the first sub-pixel, and extending in the first direction.

### CROSS-REFERENCE TO RELATED APPLICATION

The present application claims priority to, and the benefit of, Korean Patent Application No. 10-2024-0023717, filed on Feb. 19, 2024, in the Korean Intellectual Property Office, the entire disclosure of which is incorporated herein by reference.

### BACKGROUND

### 1. Field

The disclosure relates to a display device and an electronic device including the same.

### 2. Description of the Related Art

As information technology develops, importance of a display device, which is a connection medium between a user and information, is emerging.

The display device includes a plurality of pixels. Each of the pixels includes a plurality of transistors, a light-emitting element electrically connected to the transistors, and a capacitor. The transistors may be respectively turned on in response to signals provided through a line, and thus a driving current (e.g., predetermined driving current) may be generated. The light-emitting element may emit light in response to this driving current.

Recently, as the plurality of pixels and pixel circuits of the display device are miniaturized, a distance between lines included in the plurality of pixels and the pixel circuits is tended to narrow. Accordingly, a resistance of the lines included in the plurality of pixels and the pixel circuits may increase, and thus power consumption may be increased due to heat generation.

The content described above is only intended to help understanding of the background technology of the technical ideas of the disclosure, and therefore, it should not necessarily be understood as a content corresponding to prior art known to those skilled in the art of the disclosure.

### SUMMARY

Embodiments of the disclosure may provide a display device that may be driven while consuming relatively little power and an electronic device including the same.

According to embodiments of the disclosure, a display device includes a first sub-pixel including a first pixel circuit, a second sub-pixel including a second pixel circuit, and extending in a first direction from the first sub-pixel, a (1_2)-th power line overlapping the first pixel circuit, and extending in a second direction crossing the first direction, a (2_2)-th power line overlapping the second pixel circuit, and extending in the second direction, a (1_1)-th power line connecting the (1_2)-th power line and the second sub-pixel, and extending in the first direction, and a (2_1)-th power line connecting the (2_2)-th power line and the first sub-pixel, and extending in the first direction.

The display device may further include a first data line overlapping the first pixel circuit, and extending in the second direction, and a second data line overlapping the second pixel circuit, and extending in the second direction, wherein the (1_2)-th power line is between the first data line and the second data line.

The second data line may be between the (1_2)-th power line and the (2_2)-th power line.

A resistance of the (1_2)-th power line and a resistance of the (2_2)-th power line may be substantially equal.

The display device may further include a base layer, a semiconductor layer above the base layer, an interlayer insulating layer above the semiconductor layer, and defining a first via hole exposing at least a portion of the semiconductor layer overlapping the first pixel circuit, a first conductive layer above the interlayer insulating layer, a via layer above the first conductive layer, and defining a second via hole exposing at least a portion of the first conductive layer overlapping the first pixel circuit, and a second conductive layer above the via layer.

The via layer might not expose the first conductive layer overlapping the second pixel circuit.

The (1_2)-th power line of the second conductive layer may overlap the first pixel circuit, wherein the (1_2)-th power line contacts a connection electrode of the first conductive layer through the second via hole, and wherein the connection electrode contacts the first pixel circuit including the semiconductor layer through the first via hole.

The interlayer insulating layer may define a third via hole exposing at least a portion of the semiconductor layer overlapping the second pixel circuit, wherein the connection electrode extends in the first direction from the first pixel circuit to an area overlapping the second pixel circuit, and wherein the connection electrode contacts the second pixel circuit including an active layer through the third via hole on the second pixel circuit.

The display device may further include a gate layer between the semiconductor layer and the interlayer insulating layer, wherein the interlayer insulating layer defines a fourth via hole exposing at least a portion of the gate layer overlapping the second pixel circuit.

The via layer may define a fifth via hole exposing at least a portion of a fourth conductive layer overlapping the first pixel circuit.

The first sub-pixel and the second sub-pixel may include a light-emitting element, a driving transistor connected between the (1_1)-th power line and a second node for controlling a driving current supplied to the light-emitting element in response to a voltage of a first node connected to a first gate electrode, a first capacitor including one electrode connected to the first node, and another electrode connected to a third node, a second transistor connected between the third node and the first data line or the second data line, and configured to be turned on by a first scan signal, a third transistor connected between the first node and the second node, and configured to be turned on by a second scan signal, a fourth transistor connected between the first node and initialization power, and configured to be turned on by a third scan signal, and a fifth transistor connected between the (2_1)-th power line and the third node, and configured to be turned on by the second scan signal.

The display device may further include a sixth transistor connected between the second node and a fourth node connected to one electrode of the light-emitting element, and configured to be turned on by a first emission control signal, a seventh transistor connected between the fourth node and an anode initialization power line, and configured to be turned on by a fourth scan signal, and a second capacitor including one electrode connected to the (1_1)-th power line and another electrode connected to the third node.

The display device may further include a sixth transistor connected between the (1_1)-th power line and a fifth node connected to one electrode of the driving transistor, and configured to be turned on by a first emission control signal, a seventh transistor connected between the second node and a fourth node connected to one electrode of the light-emitting element, and configured to be turned on by a second emission control signal, an eighth transistor connected between the fourth node and an anode initialization power, and configured to be turned on by a fourth scan signal, and a ninth transistor connected between the fifth node and a bias power, and configured to be turned on by the fourth scan signal.

The driving transistor and the second to ninth transistors may include P-type transistors.

The second transistor, the third transistor, the fourth transistor, and the fifth transistor may include N-type transistors, wherein the driving transistor, the sixth transistor, the seventh transistor, the eighth transistor, and the ninth transistor include P-type transistors.

1 The display device may further include a tenth transistor connected between the (1_1)-th power line and the fifth node, and configured to be turned on by the second scan signal.

The first sub-pixel and the second sub-pixel may include a light-emitting element, a driving transistor connected between a second node and a fifth node for controlling a driving current supplied to the light-emitting element in response to a voltage of a first node connected to a first gate electrode, a second transistor connected between a third node and the first data line or the second data line, and configured to be turned on by a first scan signal, a first capacitor including one electrode connected to the third node, and another electrode connected to the first node, a third transistor connected between the first node and the second node connected to one electrode of the driving transistor, and configured to be turned on by a second scan signal, a fourth transistor connected between the third node and the (2_1)-th power line, and configured to be turned on by the second scan signal, and a fifth transistor connected between the (1_1)-th power line and the fifth node, and configured to be turned on by a first emission control signal.

The display device may further include a second capacitor including one electrode connected to the (1_1)-th power line, and another electrode connected to the third node, a sixth transistor connected between the second node and a fourth node connected to one electrode of the light-emitting element, and configured to be turned on by a second emission control signal, a seventh transistor connected between the fourth node and an anode initialization power line, and configured to be turned on by the first emission control signal, and an eighth transistor connected between the fifth node and a bias power, and configured to be turned on by the first scan signal.

Another aspect of the disclosure may be implemented by an electronic device. According to embodiments of the disclosure, an electronic device includes a processor configured to provide input image data, and a display device configured to display an image based on the input image data, and including a first sub-pixel including a first pixel circuit, a second sub-pixel including a second pixel circuit spaced apart from the first sub-pixel in a first direction, a (1_2)-th power line overlapping the first pixel circuit, and extending in a second direction crossing the first direction, a (2_2)-th power line overlapping the second pixel circuit, and extending in the second direction, a (1_1)-th power line connecting the (1_2)-th power line and the second sub-pixel, and extending in the first direction, and a (2_1)-th power line connecting the (2_2)-th power line and the first sub-pixel, and extending in the first direction.

The electronic device may further include a first data line overlapping the first pixel circuit, and extending in the second direction, and a second data line overlapping the second pixel circuit, and extending in the second direction, wherein the (1_2)-th power line is between the first data line and the second data line.

The display device and the electronic device including the same according to embodiments of the disclosure may be driven while consuming relatively little power.

An aspect according to embodiments is not limited to the content exemplified above, and further various aspects are included in the present specification.

### BRIEF DESCRIPTION OF THE DRAWINGS

The above and other aspects of the disclosure will become more apparent by describing in further detail embodiments thereof with reference to the accompanying drawings, in which:

FIG. 1A is a block diagram illustrating a display device according to embodiments of the disclosure;

FIG. 1B is a block diagram illustrating one or more embodiments of the display device of FIG. 1A in detail;

FIG. 2 is a block diagram illustrating one or more embodiments of one of sub-pixels of FIG. 1A and/or FIG. 1B;

FIG. 3A is a circuit diagram illustrating a sub-pixel according to one or more embodiments of the disclosure;

FIG. 3B is a circuit diagram illustrating a sub-pixel according to one or more other embodiments of the disclosure;

FIG. 3C is a circuit diagram illustrating a sub-pixel according to still one or more other embodiments of the disclosure;

FIG. 3D is a circuit diagram illustrating a sub-pixel according to further still one or more other embodiments of the disclosure;

FIG. 3E is a circuit diagram illustrating a sub-pixel according to further still one or more other embodiments of the disclosure;

FIG. 4 is a waveform diagram illustrating an operation of a display scan period according to one or more embodiments of the pixel shown in FIG. 3E;

FIG. 5 is a schematic plan view of the display panel of FIG. 2 viewed from an upper portion;

FIG. 6 is a plan view illustrating an example of a semiconductor layer included in a pixel located in the display panel of FIG. 5;

FIG. 7 is a plan view illustrating an example of a first conductive layer included in the pixel located in the display panel of FIG. 5;

FIG. 8 is a plan view illustrating an example of a second conductive layer included in the pixel located in the display panel of FIG. 5;

FIG. 9 is a plan view illustrating an example of a third conductive layer included in the pixel located in the display panel of FIG. 5;

FIG. 10 is a plan view illustrating an example of a fourth conductive layer included in the pixel located in the display panel of FIG. 5;

FIG. 11 is a plan view illustrating an example of a fifth conductive layer included in the pixel located in the display panel of FIG. 5;

FIG. 12 is a cross-sectional view illustrating a stack structure of the display panel along the line I-I′ of FIG. 5;

FIG. 13 is a cross-sectional view illustrating the stack structure of the display panel along the line II-II′ of FIG. 5;

FIG. 14 is a block diagram illustrating an electronic device including a display device according to embodiments of the disclosure;

FIG. 15 is a perspective view illustrating an example in which the electronic device of FIG. 14 is implemented as a smartphone; and

FIG. 16 is a perspective view illustrating an example in which the electronic device of FIG. 14 is implemented as a tablet PC.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

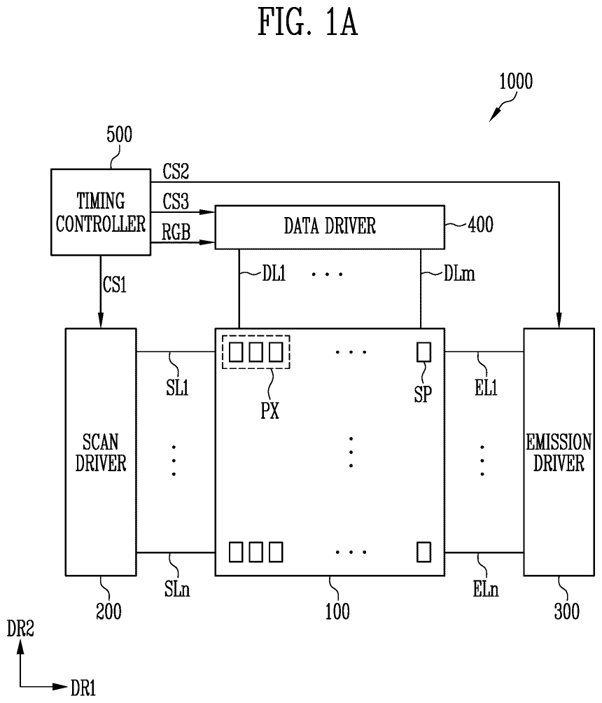

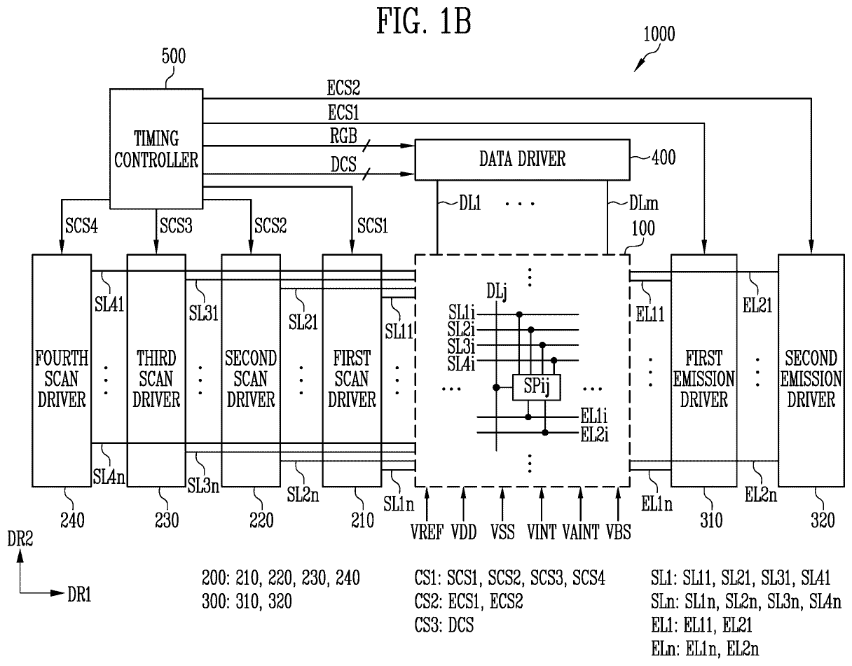

FIG. 1A is a block diagram illustrating a display device according to embodiments of the disclosure. FIG. 1B is a block diagram illustrating one or more embodiments of the display device of FIG. 1A in detail.

Referring to FIG. 1A, the display device 1000 may include a display panel 100, a scan driver 200, an emission driver 300, a data driver 400, and a timing controller 500.

The display panel 100 may include a display area AA where pixels PX are located, and a non-display area NA located in a peripheral area (for example, an edge area) of the display area AA. One or more pixels PX may be located in the display area AA.

Each of the pixels PX may include a plurality of sub-pixels SP. Each of the plurality of sub-pixels SP may emit light of one color. For example, the pixel PX may include a red sub-pixel SP that emits red light (for example, a first color), a green sub-pixel SP that emits green light (for example, a second color), and a blue sub-pixel SP that emits blue light (for example, a third color). However, a color emitted by the sub-pixel SP and a type and/or the number of sub-pixels SP are not limited thereto.

According to one or more embodiments, the sub-pixels SP may be arranged according to a stripe or PENTILET arrangement structure (PENTILE™ being a registered trademark of Samsung Display Co., Ltd., Republic of Korea), but are not limited thereto, and various embodiments may be applied to the disclosure.

Referring to FIGS. 1A and 1B, the scan driver 200 may be divided into a configuration and an operation of a first scan driver 210, a second scan driver 220, a third scan driver 230, and a fourth scan driver 240. The emission driver 300 may be divided into a configuration and an operation of a first emission driver 310 and a second emission driver 320. However, the division of the scan driver and the emission driver is for convenience of description, and according to design, at least a portion of the scan drivers and the emission drivers may be integrated into one driving circuit, module, or the like.

In one or more embodiments, the display device 1000 may further include a power supply to supply a voltage of first power VDD, a voltage of second power VSS, and voltages of third power VREF (or reference power VREF), fourth power VINT (or initialization power VINT), fifth power VAINT (or anode initialization power VAINT), and sixth power VBS (or bias power VBS) to the display panel 100. The power supply may supply low power and high power determining a gate-on level and a gate-off level of a scan signal, a control signal, and/or an emission control signal to the scan driver 200 and/or the emission driver 300. The low power may have a voltage level that is lower than that of the high power.

According to one or more embodiments, the first power VDD and the second power VSS may generate voltages for driving a light-emitting element. In one or more embodiments, a voltage level of the second power VSS may be lower than a voltage level of the first power VDD. For example, the voltage of the first power VDD may be a positive voltage, and the voltage of the second power VSS may be a ground or a negative voltage.

The third power VREF may be power that initializes the sub-pixel SP. For example, a capacitor and/or a transistor included in the sub-pixel SP may be initialized by the voltage of the third power VREF. The third power VREF may be a positive voltage.

The fourth power VINT may be power that initializes the sub-pixel SP. For example, a driving transistor included in the sub-pixel SP may be initialized by the voltage of the fourth power VINT. The fourth power VINT may be a ground or a negative voltage.

The anode initialization power VAINT may be power that initializes the sub-pixel SP. For example, an anode of the light-emitting element included in the sub-pixel SP may be initialized by the voltage of the anode initialization power VAINT. The anode initialization power VAINT may be a ground or a negative voltage.

The bias power VBS may be power for supplying an on bias voltage (e.g., predetermined on bias voltage) to a source electrode of the driving transistor included in the sub-pixel SP. The bias power VBS may be a positive voltage. In one or more embodiments, the voltage of the bias power VBS may be at a level that is similar to that of a data voltage of a black grayscale.

The display panel 100 may include sub-pixels SP respectively connected to first to n-th scan lines SL1, . . . , and SLn (n is an integer that is equal to or greater than 2), first to m-th data lines DL1, . . . , and DLm (m is an integer that is equal to or greater than 2), and first to n-th emission control lines EL1, . . . , and ELn.

Each of the first to n-th scan lines SL1, . . . , and SLn may include first to p-th sub scan lines (p is an integer that is equal to or greater than 2). For example, the first scan line SL1 may include a first sub scan line SL11, a second sub scan line SL12, a third sub scan line SL13, and a fourth sub scan line SL14 respectively connected to the first to fourth scan drivers 210, 220, 230, and 240.

Each of the first to n-th emission control lines EL1, . . . , and ELn may include first to q-th sub emission control lines (q is an integer that is equal to or greater than 2). For example, the first emission control line EL1 may include a first sub emission control line EL11 and a second sub emission control line EL21 respectively connected to the first emission driver 310 and the second emission driver 320.

The sub-pixels SP may receive the voltages of the first power VDD, the second power VSS, the third power VREF, the fourth power VINT, the fifth power VAINT, and the sixth power VBS from the outside. In one or more embodiments, a sub-pixel SPij located in an i-th (i is an integer that is equal to or greater than 2 and equal to or less than n) row, and a j-th (j is an integer that is equal to or greater than 2 and equal to or less than m) column, may be connected to sub scan lines SL1i, SL2i, SL3i, and SL4i corresponding to the i-th pixel row, sub emission control lines EL1i and EL2i corresponding to the i-th pixel row, and a data line DLj corresponding to the j-th pixel column.

The timing controller 500 may generate a first emission driving signal CS1, a second emission driving signal CS2, and a third emission driving signal CS3 in response to synchronization signals supplied from an outside (for example, from a processor or the like). For example, the first emission driving signal CS1 may include a first scan control signal SCS1, a second scan control signal SCS2, a third scan control signal SCS3, and a fourth scan control signal SCS4. In addition, the second emission driving signal CS2 may include a first emission control signal ECS1 and a second emission control signal ECS2. The third emission driving signal CS3 may include a data control signal DCS.

The timing controller 500 may generate the first scan control signal SCS1, the second scan control signal SCS2, the third scan control signal SCS3, the fourth scan control signal SCS4, the first emission control signal ECS1, the second emission control signal ECS2, and the data control signal DCS.

The first scan control signal SCS1 may be supplied to the first scan driver 210, the second scan control signal SCS2 may be supplied to the second scan driver 220, the third scan control signal SCS3 may be supplied to the third scan driver 230, and the fourth scan control signal SCS4 may be supplied to the fourth scan driver 240.

The first emission control signal ECS1 may be supplied to the first emission driver 310, and the second emission control signal ECS2 may be supplied to the second emission driver 320.

The data control signal DCS may be supplied to the data driver 400.

In addition, the timing controller 500 may rearrange input image data supplied from the outside (for example, from the processor or the like) into image data RGB, and may supply the image data RGB to the data driver 400.

The first scan control signal SCS1 may include a first scan start pulse and clock signals. The first scan start pulse may control a first timing of a scan signal output from the first scan driver 210. The clock signals may be used to shift the first scan start pulse.

The second scan control signal SCS2 may include a second scan start pulse and clock signals. The second scan start pulse may control a first timing of a scan signal output from the second scan driver 220. The clock signals may be used to shift the second scan start pulse.

The third scan control signal SCS3 may include a third scan start pulse and clock signals. The third scan start pulse may control a first timing of a scan signal output from the third scan driver 230. The clock signals may be used to shift the third scan start pulse.

The fourth scan control signal SCS4 may include a fourth scan start pulse and clock signals. The fourth scan start pulse may control a first timing of a scan signal output from the fourth scan driver 240. The clock signals may be used to shift the fourth scan start pulse.

The first emission control signal ECS1 may include a first emission control start pulse and clock signals. The first emission control start pulse may control a first timing of an emission control signal output from the first emission driver 310. The clock signals may be used to shift the first emission control start pulse.

The second emission control signal ECS2 may include a second emission control start pulse and clock signals. The second emission control start pulse may control a first timing of an emission control signal output from the second emission driver 320. The clock signals may be used to shift the second emission control start pulse.

The data control signal DCS may include a source start pulse and clock signals. The source start pulse may control a sampling start time point of data. The clock signals may be used to control a sampling operation.

The first scan driver 210 may receive the first scan control signal SCS1 from the timing controller 500, and may supply a scan signal (for example, a first scan signal) to first sub scan lines SL11 to SL1n based on the first scan control signal SCS1. For example, the first scan driver 210 may sequentially supply the first scan signal to the first scan line SL1. When the first scan signal is sequentially supplied, the sub-pixels SP may be selected in a horizontal line unit (or a pixel row unit), and a data signal may be supplied to the sub-pixels SP. That is, the first scan signal may be a signal used to write data.

The first scan signal may be set to a gate-on level (for example, a low voltage). A transistor included in the sub-pixel SP and receiving the first scan signal may be set to a turn-on state when the first scan signal is supplied.

The first scan driver 210 may supply the scan signal to the first scan line SL1 during a display scan period of one frame. For example, the first scan driver 210 may supply at least one scan signal to each first scan line SL1 during the display scan period.

The second scan driver 220 may receive the second scan control signal SCS2 from the timing controller 500, and may supply a scan signal (for example, a second scan signal) to second sub scan lines SL21 to SL2n based on the second scan control signal SCS2. For example, the second scan driver 220 may sequentially supply the second scan signal to the second scan line SL2. The second scan signal may be supplied for initialization and/or threshold voltage (Vth) compensation of the transistor and the capacitor included in the sub-pixels SP. When the second scan signal is supplied, the sub-pixels SP may perform a threshold voltage compensation operation and/or an initialization operation. The second scan signal may be set to a gate-on level (for example, a low voltage). The transistor included in the sub-pixel SP and receiving the second scan signal may be set to a turn-on state when the second scan signal is supplied.

The second scan driver 220 may supply the scan signal to the second scan line SL2 during the display scan period of one frame. For example, the second scan driver 220 may supply at least one scan signal to each second scan line SL2 during the display scan period.

The third scan driver 230 may receive the third scan control signal SCS3 from the timing controller 500, and may supply a scan signal (for example, a third scan signal) to the third sub scan line SL3 based on the third scan control signal SCS3. For example, the third scan driver 230 may supply the scan signal (for example, the third scan signal) to third sub scan lines SL31 to SL3n. The third scan signal may be supplied for initialization of the driving transistor included in the sub-pixels SP and/or initialization of the capacitor included in the sub-pixels SP. When the third scan signal is supplied, the sub-pixels SP may perform an initialization operation of the driving transistor and/or an initialization operation of the capacitor.

The third scan signal may be set to a gate-on level (for example, a low voltage). A transistor included in the sub-pixel SP and receiving the third scan signal may be set to a turn-on state when the third scan signal is supplied.

The fourth scan driver 240 may receive the fourth scan control signal SCS4 from the timing controller 500, and may supply a scan signal (for example, a fourth scan signal) to the fourth scan control signal. For example, the fourth scan driver 240 may supply the scan signal (for example, the fourth scan signal) to fourth sub scan lines SL41 to SL4n.

The fourth scan signal may be supplied for initialization of the light-emitting element included in the sub-pixels SP. In addition, the fourth scan signal may be supplied for supply of a bias voltage (for example, an on-bias voltage) to the source electrode of the driving transistor included in the sub-pixels SP. Accordingly, when the fourth scan signal is supplied, the sub-pixels SP may perform an initialization operation of the light-emitting element and/or a supply operation of the bias voltage.

The fourth scan signal may be set to a gate-on level (for example, a low voltage). A transistor included in the sub-pixel SP and receiving the fourth scan signal may be set to a turn-on state when the fourth scan signal is supplied.

The first emission driver 310 may receive the first emission control signal ECS1 from the timing controller 500, and may supply an emission control signal (for example, a first emission control signal) to the first emission control lines EL1 based on the first emission control signal ECS1. For example, the first emission driver 310 may sequentially supply the first emission control signal to first to n-th first sub emission control lines EL11 to EL1n.

The second emission driver 320 may receive the second emission control signal ECS2 from the timing controller 500, and may supply an emission control signal (for example, a second emission control signal) to the first emission control line EL1 based on the second emission control signal ECS2. For example, the second emission driver 320 may sequentially supply the second emission control signal to first to n-th second sub emission control lines EL21 to EL2n.

When the first emission control signal and/or the second emission control signal are supplied, the sub-pixels SP may not emit light in a horizontal line unit (or the pixel row unit). To this end, the first emission control signal and the second emission control signal may be set to a gate-off level (for example, a high voltage) so that the transistor included in the sub-pixels SP are turned off. The transistor included in the sub-pixel SP and receiving the first emission control signal and/or the second emission control signal may be turned off when the first emission control signal and/or the second emission control signal is supplied, and may be set to a turn-on state otherwise.

The first emission control signal and the second emission control signal may be used to control an emission time of the sub-pixels SP. To this end, the first emission control signal and the second emission control signal may be set to a width that is wider than that of the scan signal.

In one or more embodiments, the first emission control signal and/or the second emission control signal may have a plurality of gate-off level periods (for example, high voltage periods) during one frame period. For example, the first emission control signal and/or the second emission control signal may include a plurality of gate-on periods and a plurality of gate-off periods for initialization, threshold voltage compensation, and the like.

The data driver 400 may receive the data control signal DCS and the image data RGB from the timing controller 500. The data driver 400 may supply a data signal to the data lines DL in response to the data control signal DCS. The data signal supplied to the data lines DL may be supplied to the sub-pixels SP selected by the scan signal (for example, the first scan signal). In other words, the data driver 400 may supply the data signal to the data lines DL to be synchronized with the scan signal.

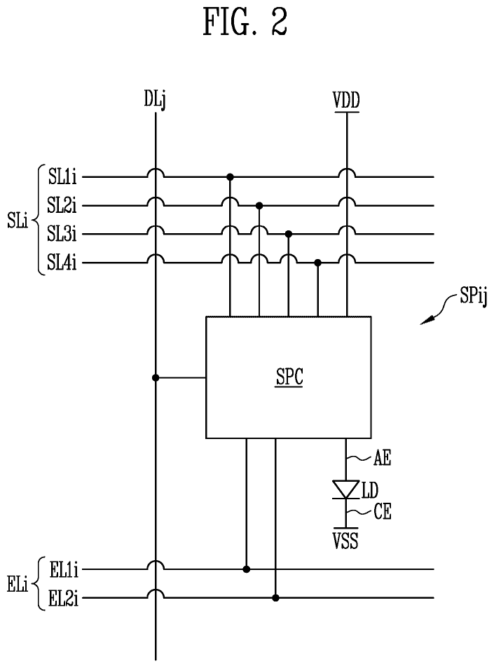

FIG. 2 is a block diagram illustrating one or more embodiments of one of the sub-pixels of FIG. 1A and/or FIG. 1B. In FIG. 2, the sub-pixel SPij arranged in the i-th row and the j-th column among the sub-pixels SP of FIG. 1A and/or 1B is shown as an example.

Referring to FIG. 2, the sub-pixel SPij may include a sub-pixel circuit SPC and a light-emitting element LD.

The light-emitting element LD may be connected between the first power VDD and the second power VSS. An anode AE electrode of the light-emitting element LD may be connected to the first power VDD through the sub-pixel circuit SPC, and a cathode CE electrode of the light-emitting element LD may be connected to the second power VSS. For example, the anode AE electrode of the light-emitting element LD may be connected to the first power VDD through one or more transistors included in the sub-pixel circuit SPC.

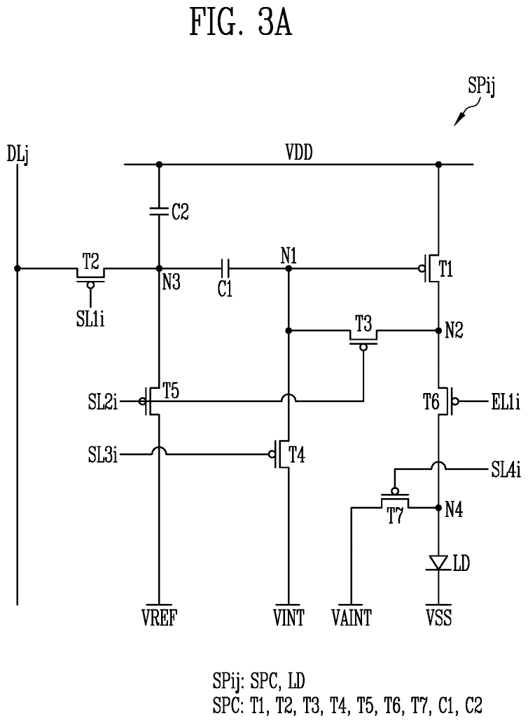

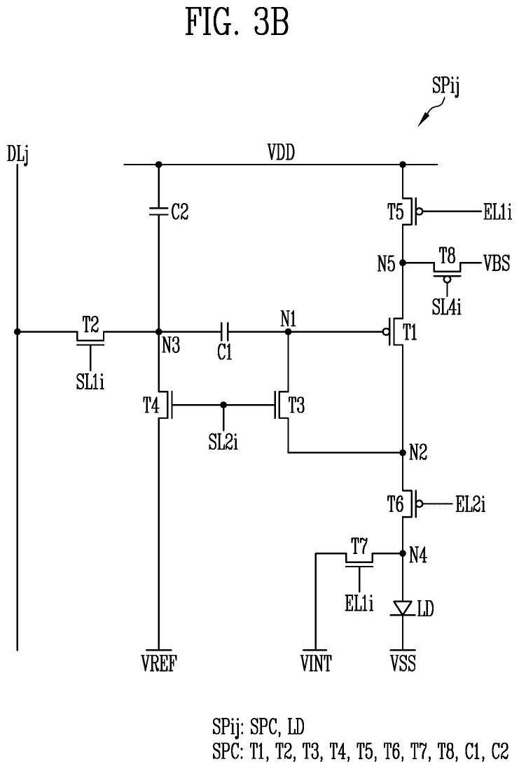

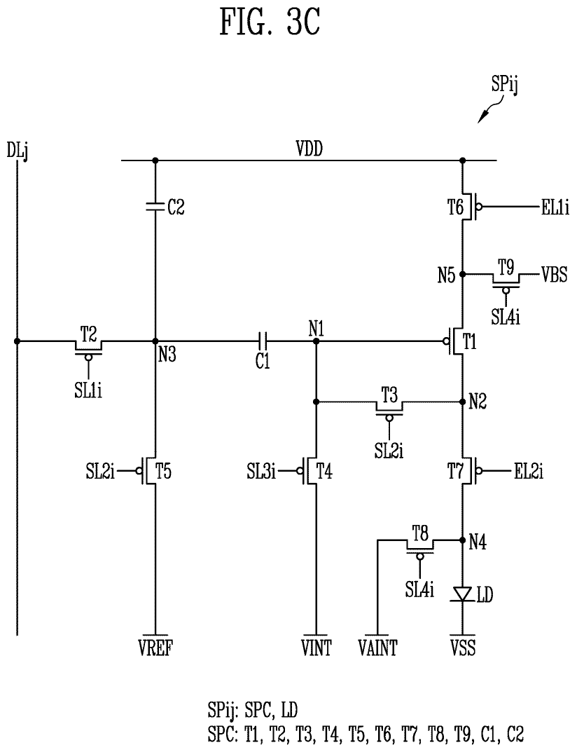

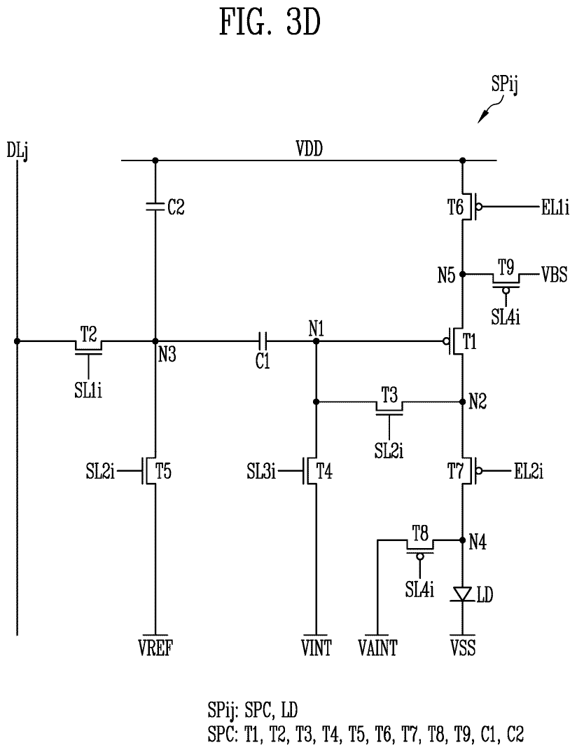

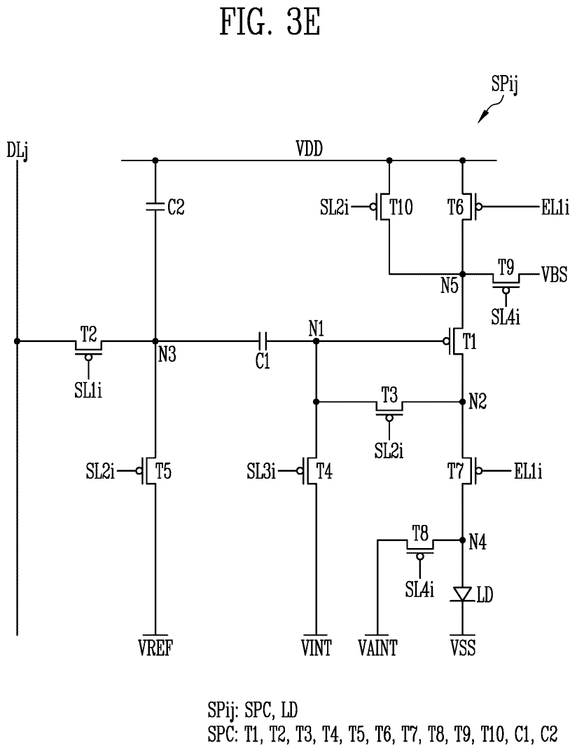

The sub-pixel circuit SPC may be connected to the first to fourth sub scan lines SL1i to SL4i, the first and second sub emission control lines EL1i and EL2i, and the data line DLj of FIG. 1B. The sub-pixel circuit SPC is configured to control the light-emitting element LD according to signals received through these signal lines. Details are described later with reference to FIGS. 3A to 3E.

FIG. 3A is a circuit diagram illustrating a sub-pixel according to one or more embodiments of the disclosure. FIG. 3B is a circuit diagram illustrating a sub-pixel according to one or more other embodiments of the disclosure. FIG. 3C is a circuit diagram illustrating a sub-pixel according to still one or more other embodiments of the disclosure. FIG. 3D is a circuit diagram illustrating a sub-pixel according to further still one or more other embodiments of the disclosure. FIG. 3E is a circuit diagram illustrating a sub-pixel according to further still one or more other embodiments of the disclosure.

For convenience of description, FIGS. 3A to 3E show the sub-pixel SPij positioned in the i-th horizontal line (or the i-th pixel row) and contacting the j-th data line DLj.

Referring to FIG. 3A, the sub-pixel SPij may include a sub-pixel circuit SPC and a light-emitting element LD.

The sub-pixel circuit SPC may include first to seventh transistors T1, T2, T3, T4, T5, T6, and T7, and first and second capacitors C1 and C2.

In FIG. 3A, the first to seventh transistors T1, T2, T3, T4, T5, T6, and T7 are shown as P-type, but are not limited thereto. For example, the third transistor T3 and the fourth transistor T4 may be N-type.

Meanwhile, the P-type transistor may be turned on by a low level of scan signal, and turned off by a high level of scan signal. In addition, the N-type transistor may be turned on by the high level of scan signal, and turned off by the low level of scan signal.

A first electrode (or an anode) of the light-emitting element LD may be connected to the sixth transistor T6, and a second electrode (or a cathode) of the light-emitting element LD may be connected to the second power VSS.

A first electrode (for example, a source electrode) of the first transistor T1 may be connected to the first power VDD, and a second electrode (for example, a drain electrode) of the first transistor T1 may contact the first electrode of the light-emitting element LD. The first transistor T1 may generate a driving current, and may provide the driving current to the light-emitting element LD. A gate electrode of the first transistor T1 may be connected to a first node N1. The first transistor T1 may function as a driving transistor of the sub-pixel SPij. The first transistor T1 may control a current amount flowing from the first power VDD to the second power VSS via the light-emitting element LD in response to a voltage applied to the first node N1.

The first capacitor C1 may be connected between a third node N3 and the first node N1 corresponding to the gate electrode of the first transistor T1. The first capacitor C1 may store a voltage corresponding to a voltage difference between the first node N1 and the third node N3.

The second capacitor C2 may be connected between the first power VDD and the third node N3. The second capacitor C2 may store a voltage corresponding to a voltage difference between the first power VDD and the third node N3. As one electrode of the second capacitor C2 is connected to the first power VDD, which is a constant voltage source, and another electrode is connected to the third node N3, the second capacitor C2 may maintain a data signal (or a data voltage), which is written to the third node N3 through the second transistor T2 in the display scan period, during a self-scan period in which the data signal is not written. That is, the second capacitor C2 may stabilize a voltage of the third node N3.

The second transistor T2 may be connected between the data line DLj and the third node N3. The second transistor T2 according to one or more embodiments may include a (2_1)-th transistor and a (2_2)-th transistor connected in series. The second transistor T2 may include a gate electrode for receiving the scan signal. For example, the gate electrode of the second transistor T2 may be connected to the first sub scan line SL1i to receive the first scan signal. The second transistor T2 may be turned on when the first scan signal is supplied to the first sub scan line SL1i to electrically connect the data line DLj and the third node N3. Accordingly, the data signal (or the data voltage) may be transmitted to the third node N3.

The third transistor T3 may be connected between the first node N1 and a second node N2. The third transistor T3 according to one or more embodiments may include a (3_1)-th transistor and a (3_2)-th transistor connected in series. The third transistor T3 may include a gate electrode for receiving the scan signal. For example, the gate electrode of the third transistor T3 may be connected to the second sub scan line SL2i to receive the second scan signal. The third transistor T3 may be turned on when the second scan signal is supplied to the second sub scan line SL2i to electrically connect the first node N1 and the second node N2. By turning on the third transistor T3, the first transistor T1 may have a diode-connection form. When the first transistor T1 has the diode-connection form, a change of a threshold voltage of the first transistor T1 may be compensated.

The fourth transistor T4 may be connected between the fourth power VINT and the first node N1. The fourth transistor T4 according to one or more embodiments may include a (4_1)-th transistor and a (4_2)-th transistor connected in series. The fourth transistor T4 may include a gate electrode for receiving the scan signal. For example, the gate electrode of the fourth transistor T4 may be connected to the third sub scan line SL3i to receive the third scan signal. The fourth transistor T4 may be turned on when the third scan signal is supplied to the third sub scan line SL3i to electrically connect the fourth power VINT and the first node N1. Accordingly, the voltage of the fourth power VINT may be supplied to the first node N1. Therefore, a voltage of the first node N1 may be initialized to the voltage of the fourth power VINT.

The fifth transistor T5 may be connected between the third power VREF and the third node N3. The fifth transistor T5 according to one or more embodiments may include a (5_1)-th transistor and a (5_2)-th transistor connected in series. The fifth transistor T5 may include a gate electrode for receiving the scan signal. For example, the gate electrode of the fifth transistor T5 may be connected to the second sub scan line SL2i to receive the second scan signal. The fifth transistor T5 may be turned on when the second scan signal is supplied to the second sub scan line SL2i to electrically connect the third power VREF and the third node N3. Accordingly, the voltage of the third power VREF may be supplied to the third node N3. Therefore, the voltage of the third node N3 may be initialized to the voltage of the third power VREF.

Meanwhile, because the gate electrodes of the third and fifth transistors T3 and T5 are connected to the same scan line (that is, the second sub scan line SL2i), third and fifth transistors T3 and T5 may be turned off or turned on concurrently or substantially simultaneously.

The sixth transistor T6 may be connected between the second node N2 and a fourth node N4. The sixth transistor T6 may include a gate electrode for receiving the emission control signal. For example, the gate electrode of the sixth transistor T6 may be connected to the first sub emission control line EL1i to receive the first emission control signal. The sixth transistor T6 may be turned off when the first emission control signal is supplied to the first sub emission control line EL1i, and may be turned on otherwise. The sixth transistor T6 of a turn-on state may electrically connect the second node N2 and the fourth node N4.

When the sixth transistor T6 is turned on, the light-emitting element LD may emit light with a luminance corresponding to the voltage of the first node N1.

The seventh transistor T7 may be connected between the fourth node N4 and the anode initialization power VAINT. The seventh transistor T7 may include a gate electrode for receiving the scan signal. For example, the gate electrode of the seventh transistor T7 may be connected to the fourth sub scan line SL4i to receive the fourth scan signal. The seventh transistor T7 may be turned on when the fourth scan signal is supplied to the fourth sub scan line SL4i to electrically connect the anode initialization power VAINT and the fourth node N4. Accordingly, a voltage of the fourth node N4 may be initialized to the voltage of the anode initialization power VAINT. When the voltage of the anode initialization power VAINT is supplied to the anode of the light-emitting element LD, a parasitic capacitor of the light-emitting element LD may be discharged. As a residual voltage charged in the parasitic capacitor is discharged (removed), unintended micro-emission may be reduced or prevented. Therefore, a black expression ability of the sub-pixel SPij may be improved. Meanwhile, by separating an initialization operation of the gate electrode of the first transistor T1 (or the first node N1) and an initialization operation of the anode of the light-emitting element LD (or the fourth node N4), the likelihood of the light-emitting element LD unintentionally emitting light during the initialization operation of the gate electrode of the first transistor T1 (or the first node N1) may be reduced or prevented.

Referring to FIG. 3B, the sub-pixel SPij may include a sub-pixel circuit SPC and a light-emitting element LD.

The sub-pixel circuit SPC may include first to eighth transistors T1, T2, T3, T4, T5, T6, T7, and T8, and first and second capacitors C1 and C2.

A first electrode (or an anode) of the light-emitting element LD may be connected to a second node N2 (e.g., via a fourth node N4 and a sixth transistor T6), and a second electrode (or a cathode) of the light-emitting element LD may be connected to the second power VSS.

A first electrode (for example, a source electrode) of the first transistor T1 may be connected to the first power VDD, and a second electrode (for example, a drain electrode) of the first transistor T1 may be connected to the first electrode of the light-emitting element LD. The first transistor T1 may generate a driving current, and may provide the driving current to the light-emitting element LD. A gate electrode of the first transistor T1 may be connected to a first node N1. The first transistor T1 may function as a driving transistor of the sub-pixel SPij. The first transistor T1 may control a current amount flowing from the first power VDD to the second power VSS via the light-emitting element LD in response to a voltage applied to the first node N1.

The first capacitor C1 may be connected between the first node N1 and a third node N3. The first capacitor C1 may store a voltage corresponding to a voltage difference between the first node N1 and the third node N3.

The second capacitor C2 may be connected between the first power VDD and the third node N3. The second capacitor C2 may store a voltage corresponding to a voltage difference between the first power VDD and the third node N3. As one electrode of the second capacitor C2 is connected to the first power VDD, which is a constant voltage source, and another electrode of the second capacitor C2 is connected to the third node N3, the second capacitor C2 may maintain a data signal (or a data voltage), which is written to the third node N3 through the second transistor T2 in the display scan period, during a self-scan period in which the data signal is not written. That is, the second capacitor C2 may stabilize a voltage of the third node N3.

The second transistor T2 may be connected between the data line DLj and the third node N3. The second transistor T2 according to one or more embodiments may include a (2_1)-th transistor and a (2_2)-th transistor connected in series. The second transistor T2 may include a gate electrode for receiving the scan signal. For example, the gate electrode of the second transistor T2 may be connected to the first sub scan line SL1i to receive the first scan signal. The second transistor T2 may be turned on when the first scan signal is supplied to the first sub scan line SL1i to electrically connect the data line DLj and the third node N3. Accordingly, the data signal (or the data voltage) may be transmitted to the third node N3.

The third transistor T3 may be connected between the first node N1 and the second node N2. The third transistor T3 according to one or more embodiments may include a (3_1)-th transistor and a (3_2)-th transistor connected in series. The third transistor T3 may include a gate electrode for receiving the scan signal. For example, the gate electrode of the third transistor T3 may be connected to the second sub scan line SL2i to receive the second scan signal. The third transistor T3 may be turned on when the second scan signal is supplied to the second sub scan line SL2i to electrically connect the first node N1 and the second node N2. By turning on the third transistor T3, the first transistor T1 may have a diode-connection form. When the first transistor T1 has the diode-connection form, a threshold voltage of the first transistor T1 may be compensated.

The fourth transistor T4 may be connected between the third power VREF and the third node N3. The fourth transistor T4 according to one or more embodiments may include a (4_1)-th transistor and a (4_2)-th transistor connected in series. The fourth transistor T4 may include a gate electrode for receiving the scan signal. For example, the gate electrode of the fourth transistor T4 may be connected to the second sub scan line SL2i to receive the second scan signal. The fourth transistor T4 may be turned on when the second scan signal is supplied to the second sub scan line SL2i to electrically connect the third power VREF and the third node N3. Accordingly, the voltage of the third power VREF may be supplied to the third node N3. Therefore, the voltage of the third node N3 may be initialized to the voltage of the third power VREF.

Meanwhile, because the gate electrodes of the third and fourth transistors T3 and T4 are connected to the same scan line (that is, the second sub scan line SL2i), third and fourth transistors T3 and T4 may be turned off or turned on concurrently or substantially simultaneously.

The fifth transistor T5 may be connected between the first power VDD and a fifth node N5. The fifth transistor T5 may include a gate electrode for receiving the emission control signal. For example, the gate electrode of the fifth transistor T5 may be connected to the first sub emission control line EL1i to receive the first emission control signal. The fifth transistor T5 may be turned off when the first emission control signal is supplied to the first sub emission control line EL1i, and may be turned on otherwise. The fifth transistor T5 of a turn-on state may connect the first electrode of the first transistor T1 to the first power VDD.

The sixth transistor T6 may be connected between the anode of the light-emitting element LD (or a fourth node N4) and the second node N2 corresponding to the second electrode of the first transistor T1. The sixth transistor T6 may include a gate electrode for receiving the emission control signal. For example, the gate electrode of the sixth transistor T6 may be connected to the second sub emission control line EL2i to receive the second emission control signal. The sixth transistor T6 may be turned off when the second emission control signal is supplied to the second sub emission control line EL2i, and may be turned on otherwise. The sixth transistor T6 of a turn-on state may electrically connect the second node N2 and the fourth node N4.

When both of the fifth and sixth transistors T5 and T6 are turned on, the light-emitting element LD may emit light with a luminance corresponding to a voltage of the first node N1.

In one or more embodiments, when the fifth transistor T5 is turned on and the sixth transistor T6 is turned off, threshold voltage compensation of the first transistor T1 may be performed.

The seventh transistor T7 may be connected between the first electrode of the light-emitting element LD (or the fourth node N4) and the anode initialization power VAINT. The seventh transistor T7 may include a gate electrode for receiving the emission control signal. For example, the gate electrode of the seventh transistor T7 may be connected to the first sub emission control line EL1i to receive the first emission control signal. The seventh transistor T7 may be turned on when the first emission control signal is supplied to the first sub emission control line EL1i to electrically connect the fourth power VINT and the fourth node N4. Accordingly, a voltage of the fourth node N4 (or the anode of the light-emitting element LD) may be initialized to the voltage of the fourth power VINT.

The eighth transistor T8 may be connected between the first electrode of the first transistor T1 (or the fifth node N5) and the bias power VBS. The eighth transistor T8 may include a gate electrode for receiving the scan signal. For example, the gate electrode of the eighth transistor T8 may be connected to the fourth sub scan line SL4i to receive the fourth scan signal. The eighth transistor T8 may be turned on when the fourth scan signal is supplied to the fourth sub scan line SL4i to electrically connect the fifth node N5 and the bias power VBS. Using the eighth transistor T8, a bias may be periodically applied to the source electrode of the driving transistor (for example, the first transistor T1) at a constant voltage. Therefore, a hysteresis deviation due to a grayscale difference between adjacent pixels may be eliminated, and screen drag due to this may be reduced (eliminated).

Referring to FIG. 3B, the second transistor T2, the third transistor T3, the fourth transistor T4, and the seventh transistor T7 may be implemented as N-type transistors. However, embodiments of the disclosure are not limited thereto. For example, at least one of the second transistor T2, the third transistor T3, the fourth transistor T4, or the seventh transistor T7 may be implemented as a P-type transistor, and at least one of the fifth transistor T5 or the sixth transistor T6 may be implemented as an N-type transistor.

Referring to FIGS. 3C and 3D, the sub-pixel SPij may include a sub-pixel circuit SPC and a light-emitting element LD.

The sub-pixel circuit SPC may include first to ninth transistors T1, T2, T3, T4, T5, T6, T7, T8, and T9, and first and second capacitors C1 and C2.

The first transistor T1, the second transistor T2, the third transistor T3, the fourth transistor T4, the fifth transistor T5, the eighth transistor T8, the first capacitor C1, the second capacitor C2, and the light-emitting element LD of FIGS. 3C and 3D may be described similarly to first transistor T1, the second transistor T2, the third transistor T3, the fourth transistor T4, the fifth transistor T5, the seventh transistor T7, the first capacitor C1, the second capacitor C2, and the light-emitting element LD of FIG. 3A, respectively. An overlapping description for the above-described configurations is omitted.

The sixth transistor T6 may be connected between the first power VDD and the first electrode of the first transistor T1 (or the fifth node N5). The sixth transistor T6 may include a gate electrode for receiving the emission control signal. For example, the gate electrode of the sixth transistor T6 may be connected to the first sub emission control line EL1i to receive the first emission control signal. The sixth transistor T6 may be turned off when the first emission control signal is supplied to the first sub emission control line EL1i, and may be turned on otherwise. The sixth transistor T6 of a turn-on state may connect the first electrode of the first transistor T1 to the first power VDD.

The seventh transistor T7 may be connected between the anode of the light-emitting element LD (or the fourth node N4) and the second node N2 corresponding to the second electrode of the first transistor T1. The seventh transistor T7 may include a gate electrode for receiving the emission control signal. For example, the gate electrode of the seventh transistor T7 may be connected to the second sub emission control line EL2i to receive the second emission control signal. The seventh transistor T7 may be turned off when the second emission control signal is supplied to the second sub emission control line EL2i, and may be turned on otherwise. The seventh transistor T7 of a turn-on state may electrically connect the second node N2 and the fourth node N4.

The ninth transistor T9 may be connected between the first electrode of the first transistor T1 (or the fifth node N5) and the bias power VBS. The ninth transistor T9 may include a gate electrode for receiving the scan signal. For example, the gate electrode of the ninth transistor T9 may be connected to the fourth sub scan line SL4i to receive the fourth scan signal. The ninth transistor T9 may be turned on when the fourth scan signal is supplied to the fourth sub scan line SL4i to electrically connect the fifth node N5 and the bias power VBS. Using the ninth transistor T9, a bias may be periodically applied to the source electrode of the first transistor T1 at a constant voltage.

Referring to FIG. 3D, the second transistor T2, the third transistor T3, the fourth transistor T4, and the fifth transistor T5 may be implemented as N-type transistors. However, embodiments of the disclosure are not limited thereto. For example, at least one of the second transistor T2, the third transistor T3, the fourth transistor T4, or the fifth transistor T5 may be implemented as a P-type transistor.

According to one or more embodiments of the disclosure, the third transistor T3 and the fourth transistor T4 of the sub-pixel SPij may be configured as N-type, and thus the first transistor T1 may be driven with improved reliability. For example, the third transistor T3 and the fourth transistor T4 of the sub-pixel SPij may be configured as N-type, and thus a leakage current flowing through the first node N1 to which the gate electrode of the first transistor T1 is connected may be reduced or prevented. Accordingly, the voltage of the first node N1 may be maintained relatively constant, and reliability of driving the sub-pixel SPij may be improved.

Referring to FIG. 3E, the sub-pixel SPij may include a sub-pixel circuit SPC and a light-emitting element LD.

The sub-pixel circuit SPC may include first to tenth transistors T1, T2, T3, T4, T5, T6, T7, T8, T9, and T10, and first and second capacitors C1 and C2.

The first transistor T1, the second transistor T2, the third transistor T3, the fourth transistor T4, the fifth transistor T5, the sixth transistor T6, the eighth transistor T8, the ninth transistor T9, the first capacitor C1, the second capacitor C2, and the light-emitting element LD of FIG. 3E may be described similarly to the first transistor T1, the second transistor T2, the third transistor T3, the fourth transistor T4, the fifth transistor T5, the sixth transistor T6, the eighth transistor T8, the ninth transistor T9, the first capacitor C1, the second capacitor C2, and the light-emitting element LD of FIG. 3C, respectively.

The seventh transistor T7 may be connected between the anode of the light-emitting element LD (or the fourth node N4) and the second node N2 corresponding to the second electrode of the first transistor T1. The seventh transistor T7 may include a gate electrode for receiving the emission control signal. For example, the gate electrode of the seventh transistor T7 may be connected to the first sub emission control line EL1i to receive the first emission control signal. The seventh transistor T7 may be turned off when the first emission control signal is supplied to the first sub emission control line EL1i, and may be turned on otherwise. The seventh transistor T7 of a turn-on state may electrically connect the second node N2 and the fourth node N4. However, embodiments of the disclosure are not limited thereto. For example, the gate electrode of the seventh transistor T7 may be connected to the second sub emission control line EL2i to receive the second emission control signal.

The tenth transistor T10 may be connected between the first power VDD and the fifth node N5. The tenth transistor T10 may include a gate electrode for receiving the scan signal. For example, the gate electrode of the tenth transistor T10 may be connected to the second sub scan line SL2i to receive the second scan signal. The tenth transistor T10 may be turned on when the second scan signal is supplied to the second sub scan line SL2i to electrically connect the fifth node N5 and the first power VDD.

Meanwhile, each of the first to tenth transistors T1, T2, T3, T4, T5, T6, T7, T8, T9, and T10 of FIGS. 3A to 3E may include an amorphous silicon semiconductor, a monocrystalline silicon semiconductor, a polycrystalline silicon semiconductor, an oxide semiconductor, or the like.

For example, a transistor including an N-type semiconductor layer may include a polycrystalline silicon semiconductor. However, embodiments of the disclosure are not limited thereto.

For example, a transistor including a P-type semiconductor layer may include an oxide semiconductor. The oxide semiconductor may include, for example, a metal oxide semiconductor, and the metal oxide semiconductor may include, for example, indium gallium zinc oxide (IGZO). However, embodiments of the disclosure are not limited thereto.

In one or more embodiments in which one sub-pixel includes both of a transistor including an N-type semiconductor layer and a transistor including a P-type semiconductor layer, the P-type semiconductor layer and the N-type semiconductor layer may be formed in layers different from each other. For example, the N-type semiconductor layer may be formed first, and the P-type semiconductor layer may be formed in a subsequent process. However, embodiments of the disclosure are not limited thereto.

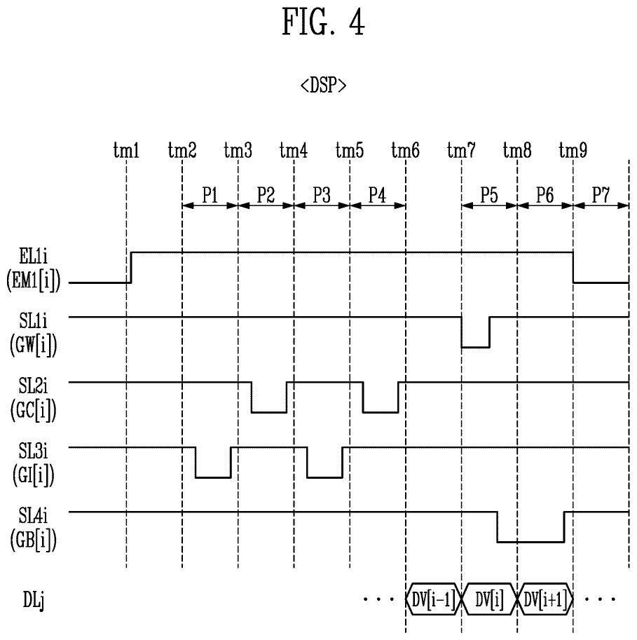

FIG. 4 is a waveform diagram illustrating an operation of the display scan period according to one or more embodiments of the pixel shown in FIG. 3E.

Hereinafter, for convenience of description, the disclosure is described based on the the pixel shown in FIG. 3E. However, the disclosure is not limited thereto.

Referring to FIGS. 3E and 4, the sub-pixel SPij may receive signals for image display during the display scan period DSP. The display scan period DSP may include a period in which a data signal DV corresponding to an output image is written. For example, the sub-pixel SPij located in the i-th row and the j-th column may receive the data signal DV from the data line DLj.

A first emission control signal EM1[i] may be supplied to the first sub emission control line EL1i, and first to fourth scan signals GW[i], GC[i], GI[i], and GB[i] may be respectively supplied to the first to fourth sub scan lines SL1i, SL2i, SL3i, and SL4i.

At a first time point tm1, the first emission control signal EM1[i] may transit from the gate-on level to the gate-off level. Accordingly, the sixth transistor T6 and the seventh transistor T7 may be turned off.

In a first period P1 (for example, between a second time point tm2 and a third time point tm3), the third scan signal GI[i] may transit from the gate-off level to the gate-on level. Accordingly, the fourth transistor T4 may be turned on. Accordingly, the voltage of the fourth power VINT may be supplied to the first node N1 (or the gate electrode of the first transistor T1), and the first node N1 may be initialized to the voltage of the fourth power VINT.

In a second period P2 (for example, between the second time point tm2 and a third time point tm3), the second scan signal GC[i] may transit from the gate-off level to the gate-on level. Accordingly, the third transistor T3 may be turned on. However, because the first emission control signal EM1[i] maintains the gate-off level and the seventh transistor T7 maintains a turn-off state, the likelihood of the voltage of the fourth power VINT, which is supplied to the first node N1, being also supplied to the fourth node N4 may be reduced or prevented, thereby reducing or preventing the likelihood of the light-emitting element LD unintentionally emitting light.

In addition, the fifth transistor T5 may be turned on by the second scan signal GC[i] of the gate-on level in the second period P2. Accordingly, the voltage of the third power VREF may be supplied to the third node N3, and the third node N3 may be initialized to the voltage of the third power VREF.

In the second period P2, the tenth transistor T10 may be turned on by the second scan signal GC[i] of the gate-on level. Accordingly, the voltage of the first power VDD may be supplied to the fifth node N5. However, because the first emission control signal EM1[i] is the gate-off level and the seventh transistor T7 is in a turn-off state, the light-emitting element LD may not emit light.

In a third period P3 (for example, between a fourth time point tm4 and a fifth time point tm5), the third scan signal GI[i] may transit from the gate-off level to the gate-on level. Accordingly, the fourth transistor T4 may be turned on. Accordingly, the voltage of the fourth power VINT may be supplied to the first node N1 (or the gate electrode of the first transistor T1), and the first node N1 may be initialized to the voltage of the fourth power VINT.

In the fourth period P4 (for example, between the fifth time point tm5 and a sixth time point tm6), the second scan signal GC[i] may transit from the gate-off level to the gate-on level. Accordingly, the third transistor T3 may be turned on. However, because the first emission control signal EM1[i] maintains the gate-off level such that the seventh transistor T7 maintains a turn-off state, the likelihood of the voltage of the fourth power VINT, which is supplied to the first node N1, being supplied to the fourth node N4 may be reduced or prevented, thereby reducing or preventing the likelihood of the light-emitting element LD unintentionally emitting light.

In addition, the fifth transistor T5 may be turned on by the second scan signal GC[i] of the gate-on level in the fourth period P4. Accordingly, the voltage of the third power VREF may be supplied to the third node N3, and the third node N3 may be initialized to the voltage of the third power VREF.

In the fourth period P4, the tenth transistor T10 may be turned on by the second scan signal GC[i] of the gate-on level. Accordingly, the voltage of the first power VDD may be supplied to the fifth node N5. However, because the first emission control signal EM1[i] is the gate-off level such that the seventh transistor T7 is in a turn-off state, the light-emitting element LD may not emit light.

At the sixth time point tm6, the second scan signal GC[i] may transit from the gate-on level to the gate-off level. Accordingly, the third transistor T3, the fifth transistor T5, and the tenth transistor T10 may be turned off.

At a seventh time point tm7, the first scan signal GW[i] may transit from the gate-off level to the gate-on level. Accordingly, the second transistor T2 may be turned on. The second transistor T2 may remain in a turned on state during a fifth period P5. Accordingly, an i-th data signal Dv[i] may be supplied to the third node N3 during the fifth period P5. Between the sixth time point tm6 and the seventh time point tm7, a data signal DV[i−1] written to an (i−1)-th pixel row may be supplied to the data line DLj. A change amount of the voltage of the third node N3 (that is, “DATA-VREF”) may be reflected in the first node N1 by the first capacitor C1. Therefore, the voltage of the first node N1 may change to “VDD−Vth+ (DATA−VREF)”. Here, DATA may be a voltage corresponding to the data signal DV[i], VREF may be the voltage of the third power, VDD may be the voltage of the first power, and Vth may be the threshold voltage of the first transistor T1.

Accordingly, the data signal DV[i] may be written to the sub-pixel SPij during the fifth period P5 from the seventh time point tm7 to an eighth time point tm8 shown in FIG. 4. That is, the fifth period P5 may be a data-writing period.

In one or more embodiments, a length of the fifth period P5, that is, a length (pulse width) of the first scan signal GW[i], may be 1 horizontal period (1H). However, the length of the first scan signal GW[i] is not limited thereto. For example, the length of the first scan signal GW[i] may be 2 horizontal periods (2H) or more.

At the eighth time point tm8, the first scan signal GW[i] may transit from the gate-on level to the gate-off level. Accordingly, the second transistor T2 may be turned off.

Between the eighth time point tm8 and a ninth time point tm9, the fourth scan signal GB[i] may transit from the gate-off level to the gate-on level. In other words, the fourth scan signal GB[i] may transit from the gate-off level to the gate-on level during the sixth period P6. Accordingly, the eighth transistor T8 may be turned on, and thus the voltage of the anode initialization power VAINT may be supplied to the fourth node N4. That is, the anode initialization of the light-emitting element LD may be performed in the sixth period P6.

In addition, the ninth transistor T9 may be turned on, and thus the voltage of the bias power VBS may be supplied to the fifth node N5 (or the source electrode of the first transistor T1). Therefore, the voltage of the bias power VBS may be supplied to the first electrode (or the source electrode) of the first transistor T1.

Accordingly, an on-bias may be applied to the first transistor T1 during the sixth period P6 from the eighth time point tm8 to the ninth time point tm9 shown in FIG. 4. That is, the sixth period P6 may be an on-bias period.

At the ninth time point tm9, the fourth scan signal GB[i] may transit from the gate-on level to the gate-off level. Accordingly, the eighth transistor T8 and the ninth transistor T9 may be turned off.

By applying the on-bias to the first transistor T1 in the sixth period P6, a hysteresis characteristic (that is, a change of the threshold voltage) of the first transistor T1 may be improved.

At the ninth time point tm9, the first emission control signal EM1[i] may transit from the gate-off level to the gate-on level. Accordingly, the sixth transistor T6 may be turned on, and thus the first electrode (for example, the source electrode) of the first transistor T1 may be connected to the first power VDD. In addition, because the seventh transistor T7 may be turned on, the sub-pixel SPij may emit light in the seventh period P7 after the ninth time point tm9 shown in FIG. 4. That is, the seventh period P7 may be an emission period.

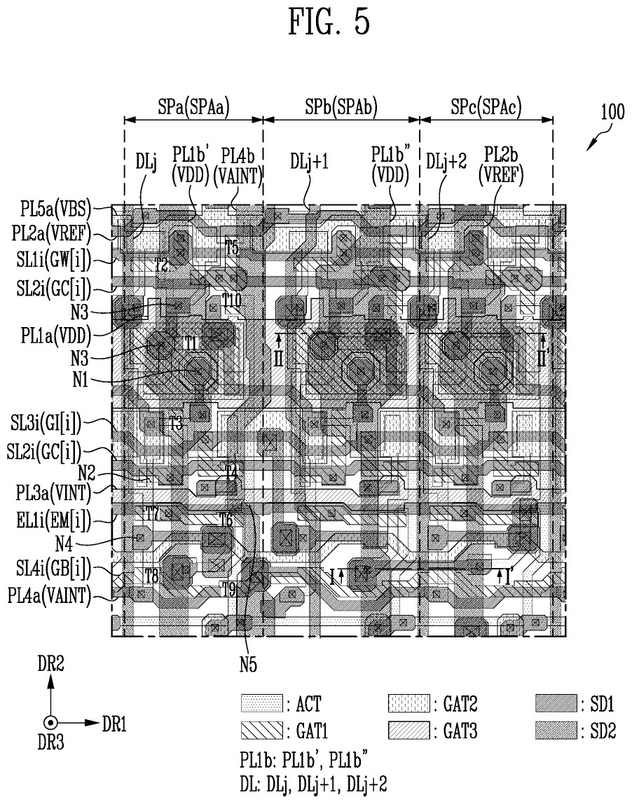

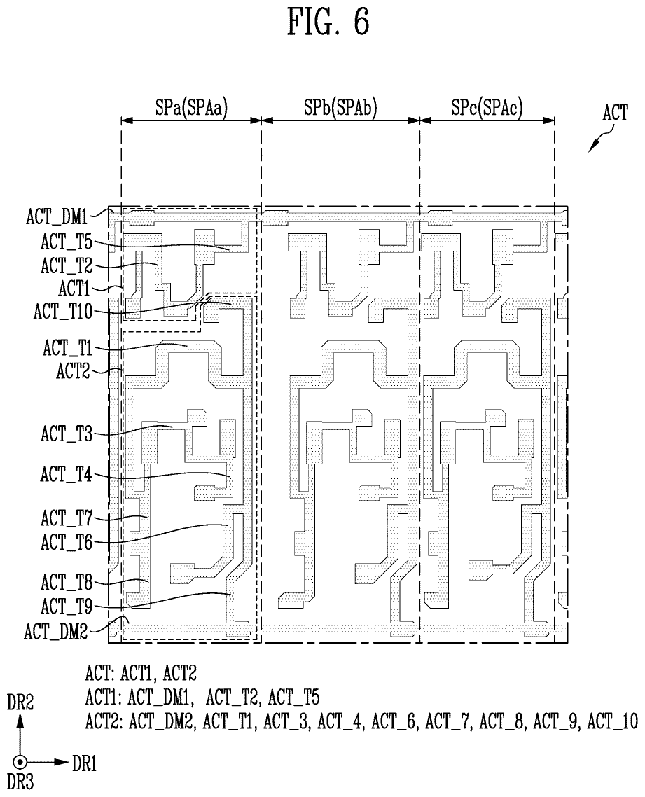

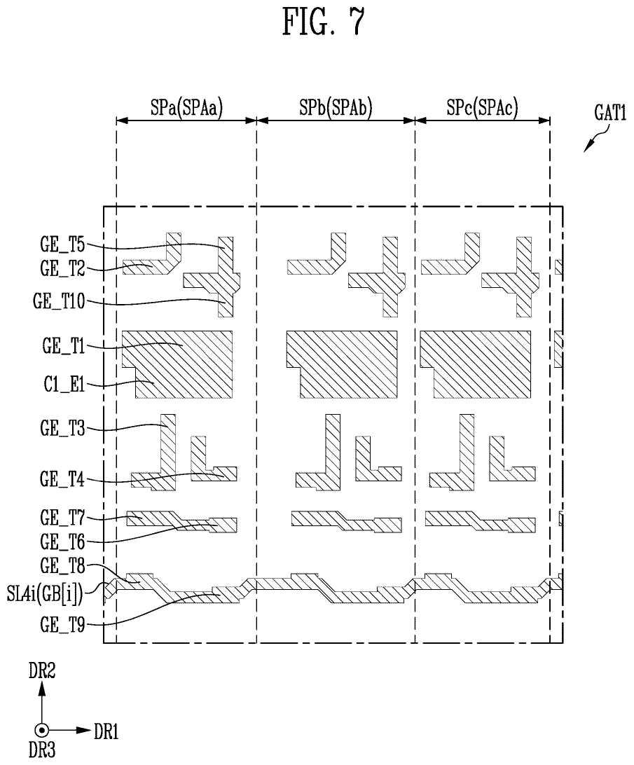

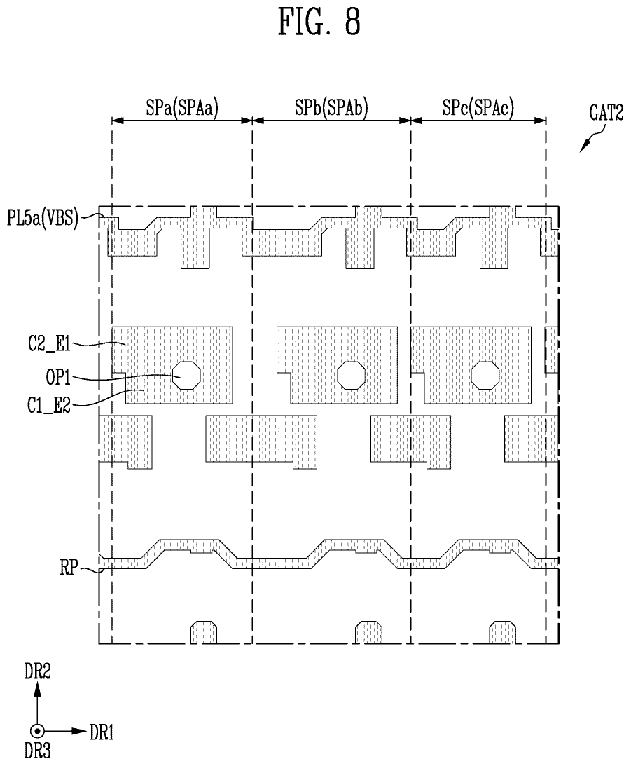

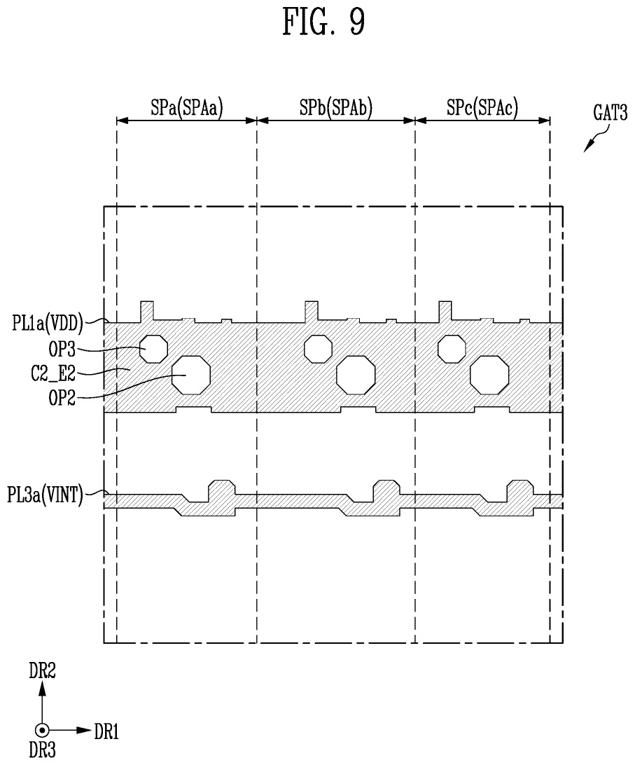

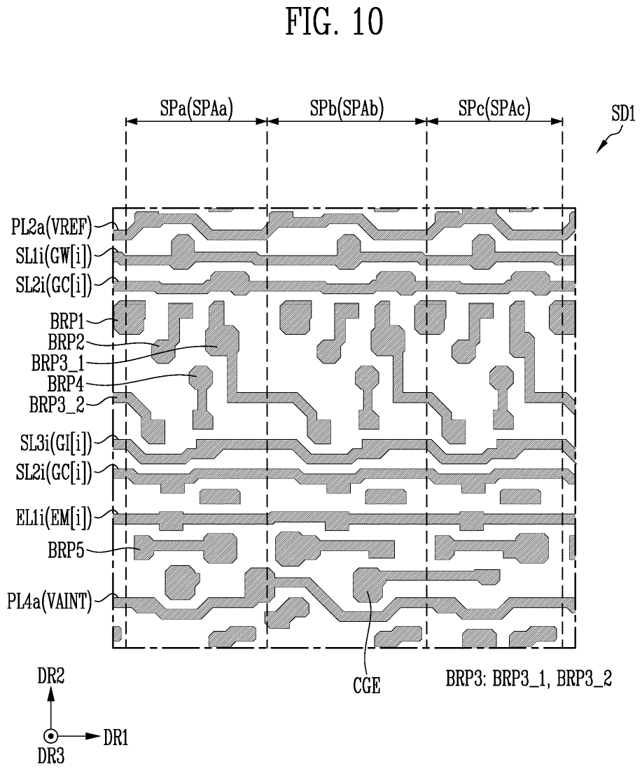

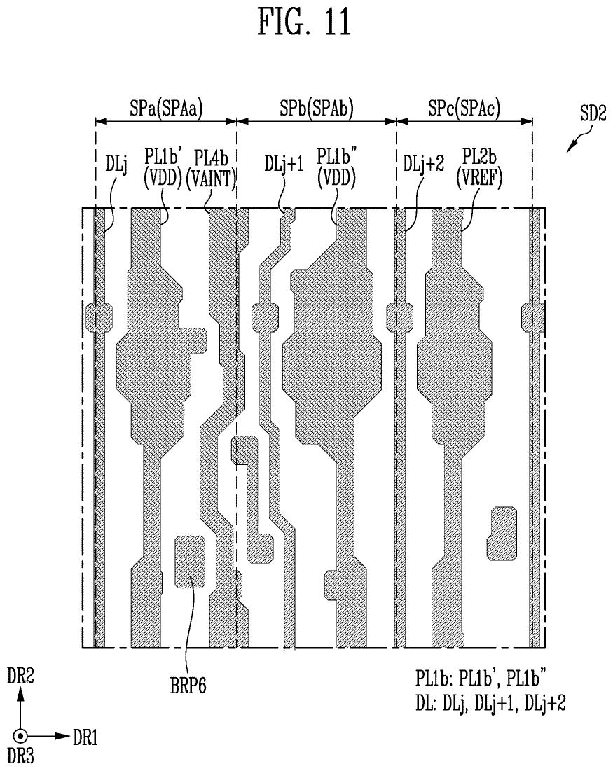

FIG. 5 is a schematic plan view of the display panel of FIG. 2 viewed from an upper portion. FIG. 6 is a plan view illustrating an example of a semiconductor layer included in a pixel located in the display panel of FIG. 5. FIG. 7 is a plan view illustrating an example of a first conductive layer included in the pixel located in the display panel of FIG. 5. FIG. 8 is a plan view illustrating an example of a second conductive layer included in the pixel located in the display panel of FIG. 5. FIG. 9 is a plan view illustrating an example of a third conductive layer included in the pixel located in the display panel of FIG. 5. FIG. 10 is a plan view illustrating an example of a fourth conductive layer included in the pixel located in the display panel of FIG. 5. FIG. 11 is a plan view illustrating an example of a fifth conductive layer included in the pixel located in the display panel of FIG. 5.

Referring to FIG. 5, the display panel 100 may include a first sub-pixel SPa (or a first sub-pixel area SPAa), a second sub-pixel SPb (or a second sub-pixel area SPAb), and a third sub-pixel SPc (or a third sub-pixel area SPAc). The first sub-pixel SPa, the second sub-pixel SPb, and the third sub-pixel SPc may form one unit pixel.

According to one or more embodiments, the first to third sub-pixels SPa, SPb, and SPc may emit light in different colors. For example, the first sub-pixel SPa may be a red pixel that emits red light, the second sub-pixel SPb may be a green pixel that emits green light, and the third sub-pixel SPc may be a blue pixel that emits blue light. However, a color, a type, the number, and/or the like of sub-pixels configuring a unit pixel is not particularly limited, and for example, the color of light emitted by each of the sub-pixels may be variously changed. According to one or more embodiments, the first to third sub-pixels SPa, SPb, and SPc may generate light of the same wavelength band, and may be configured to emit light of various wavelengths through an external configuration (for example, a color filter or the like).

The first to third sub-pixels SPa, SPb, and SPc (or pixel-driving circuits of the first to third sub-pixels SPa, SPb, and SPc) may be formed to be substantially identical to or similar to each other. Hereinafter, the disclosure is described based on the first sub-pixel SPa, and a description of the first sub-pixel Spa may also be applied to the second sub-pixel SPb and the third sub-pixel SPc. An overlapping description is omitted.

The first sub-pixel SPa (or a sub-pixel circuit of the first sub-pixel Spa) may include a semiconductor layer ACT, a first conductive layer GAT1 (or a first gate layer), a second conductive layer GAT2 (or a second gate layer), a third conductive layer GAT3 (or a third gate layer), a fourth conductive layer SD1, and a fifth conductive layer SD2. The semiconductor layer ACT, the first conductive layer GAT1, the second conductive layer GAT2, the third conductive layer GAT3, the fourth conductive layer SD1, and the fifth conductive layer SD2 may be formed in different layers through different processes.

The semiconductor layer ACT, the first conductive layer GAT1, the second conductive layer GAT2, the third conductive layer GAT3, the fourth conductive layer SD1, and the fifth conductive layer SD2 may configure the above-described sub-pixel circuit SPC (refer to FIG. 3E).

Referring to FIGS. 5 and 6, the semiconductor layer ACT may be an active layer forming a channel of the first to tenth transistors T1, T2, T3, T4, T5, T6, T7, T8, T9, and T10. The semiconductor layer ACT may include a source area (or a first area) contacting a first electrode (for example, a source electrode) of each of the first to tenth transistors T1, T2, T3, T4, T5, T6, T7, T8, T9, and T10, and a drain area (or a second area) contacting a second electrode (for example, a drain electrode). An area between the source area and the drain area may be a channel area. The channel area of the semiconductor layer ACT may be a semiconductor pattern that is not doped with an impurity and may be an intrinsic semiconductor. The source area and drain area may be a semiconductor pattern doped with an impurity.

The semiconductor layer ACT may include a first semiconductor pattern group ACT1 and a second semiconductor pattern group ACT2.

Referring to FIG. 6, the first semiconductor pattern group ACT1 may include a first dummy portion ACT_DM1, a second semiconductor pattern ACT_T2, and a fifth semiconductor pattern ACT_T5. The second semiconductor pattern ACT_T2 may configure a channel of the second transistor T2, and the fifth semiconductor pattern ACT_T5 may configure a channel of the fifth transistor T5.

The first dummy portion ACT_DM1 may extend in a first direction DR1 and may be positioned adjacent to one side of a first sub-pixel area SPAa. The first dummy portion ACT_DM1 may continuously extend in the first sub-pixel area SPAa, a second sub-pixel area SPAb, and a third sub-pixel area SPAc. The first dummy portion ACT_DM1 may connect the first semiconductor pattern group ACT1 of each of the first sub-pixel SPa, the second sub-pixel SPb, and the third sub-pixel SPc to each other in the first direction DR1.

The second semiconductor pattern group ACT2 may include a second dummy portion ACT_DM2, a first semiconductor pattern ACT_T1, a third semiconductor pattern ACT_T3, a fourth semiconductor pattern ACT_T4, a sixth semiconductor pattern ACT_T6, a seventh semiconductor pattern ACT_T7, an eighth semiconductor pattern ACT_T8, a ninth semiconductor pattern ACT_T9, and a tenth semiconductor pattern ACT_T10.

The second dummy portion ACT_DM2 may extend in the first direction DR1, and may be positioned adjacent to another side of the first sub-pixel area SPAa. The second dummy portion ACT_DM2 may continuously extend in the first sub-pixel area SPAa, the second sub-pixel area SPAb, and the third sub-pixel area SPAc. The second dummy portion ACT_DM2 may connect the second semiconductor pattern group ACT2 of each of the first sub-pixel SPa, the second sub-pixel SPb, and the third sub-pixel SPc to each other in the first direction DR1.

The first semiconductor pattern ACT_T1 may configure a channel of the first transistor T1. The third semiconductor pattern ACT_T3 may configure a channel of the third transistor T3. The fourth semiconductor pattern ACT_T4 may configure a channel of the fourth transistor T4. The sixth semiconductor pattern ACT_T6 may configure a channel of the sixth transistor T6. The seventh semiconductor pattern ACT_T7 may configure a channel of the seventh transistor T7. The eighth semiconductor pattern ACT_T8 may configure a channel of the eighth transistor T8. The ninth semiconductor pattern ACT_T9 may configure a channel of the ninth transistor T9. The tenth semiconductor pattern ACT_T10 may configure a channel of the tenth transistor T10.

Referring to FIGS. 3E, 5, and 6, a portion where the first semiconductor pattern ACT_T1, the third semiconductor pattern ACT_T3, and the seventh semiconductor pattern ACT_T7 are connected may be configured as the second node N2. A portion where the seventh semiconductor pattern ACT_T7 and the eighth semiconductor pattern ACT_T8 are connected may be configured as the fourth node N4. A portion where the first semiconductor pattern ACT_T1, the sixth semiconductor pattern ACT_T6, and the ninth semiconductor pattern ACT_T9 are connected may be configured as the fifth node N5.

Referring to FIGS. 5 to 7, the first conductive layer GAT1 may include an eleventh capacitor electrode C1_E1, gate patterns GE_T2, GE_T3, GE_T4, GE_T5, GE_T6, GE_T7, GE_T8, GE_T9, and GE_T10 of the second to tenth transistors T2 to T10, and the fourth sub scan line SL4i.

The eleventh capacitor electrode C1_E1 may have a corresponding area, may be generally positioned at a center of the first sub-pixel area SPAa, and may overlap the first semiconductor pattern ACT_T1. According to one or more embodiments, the eleventh capacitor electrode C1_E1 may configure the gate pattern GE_T1 of the first transistor T1.

The gate pattern GE_T2 of the second transistor T2 may extend in the first direction DR1, may be branched in the second direction DR2, and may overlap a channel area formed in the second semiconductor pattern ACT_T2. For example, a portion of the gate pattern GE_T2 of the second transistor T2 extending in the first direction DR1 may overlap the channel area formed in the second semiconductor pattern ACT_T2 to configure a gate electrode of the second transistor T2.

The gate pattern GE_T3 of the third transistor T3 may extend in the first direction DR1, may be branched in the second direction DR2, and may overlap a channel area formed in the third semiconductor pattern ACT_T3. For example, a portion of the gate pattern GE_T3 of the third transistor T3 branched in the second direction DR2 may overlap the channel area formed in the third semiconductor pattern ACT_T3 to configure a gate electrode of the third transistor T3.

The gate pattern GE_T4 of the fourth transistor T4 may extend in a direction opposite to the first direction DR1, may be branched in a second direction DR2, and may overlap a channel area formed in the fourth semiconductor pattern ACT_T4. For example, a portion of the gate pattern GE_T4 of the fourth transistor T4 branched in the second direction DR2 may overlap the channel area formed in the fourth semiconductor pattern ACT_T4 to configure a gate electrode of the fourth transistor T4.

As shown in FIG. 7, the gate pattern GE_T5 of the fifth transistor T5 and the gate pattern GE_T10 of the tenth transistor T10 may be formed integrally. However, the disclosure is not limited thereto.

The gate pattern GE_T5 of the fifth transistor T5 may extend in the first direction DR1, may be branched in the second direction DR2, and may overlap a channel area formed in the fifth semiconductor pattern ACT_T5. For example, a portion of the gate pattern GE_T5 of the fifth transistor T5 branched in the second direction DR2 may overlap the channel area formed in the fifth semiconductor pattern ACT_T5 to configure a gate electrode of the fifth transistor T5.

The gate pattern GE_T10 of the tenth transistor T10 may extend in the first direction DR1, may be branched in a direction opposite to the second direction DR2, and may overlap a channel area formed in the tenth semiconductor pattern ACT_T10. For example, a portion of the gate pattern GE_T10 of the tenth transistor T10 branched in the direction opposite to the second direction DR2 may overlap the channel area formed in the tenth semiconductor pattern ACT_T10 to configure a gate electrode of the tenth transistor T10.

As shown in FIG. 7, the gate pattern GE_T6 of the sixth transistor T6 and the gate pattern GE_T7 of the seventh transistor T7 may be formed integrally. However, the disclosure is not limited thereto.

The gate pattern GE_T6 of the sixth transistor T6 may extend in the first direction DR1, and may overlap a channel area formed in the sixth semiconductor pattern ACT_T6. For example, one end of the gate pattern GE_T6 of the sixth transistor T6 extending in the first direction DR1 may overlap the channel area formed in the sixth semiconductor pattern ACT_T6 to configure a gate electrode of the sixth transistor T6.

The gate pattern GE_T7 of the seventh transistor T7 may extend in the direction opposite to the first direction DR1 from the gate pattern GE_T6 of the sixth transistor T6, and may overlap a channel area formed in the seventh semiconductor pattern ACT_T7. For example, another end of the gate pattern GE_T7 of the seventh transistor T7 extending in the direction opposite to the first direction DR1 may overlap the channel area formed in the seventh semiconductor pattern ACT_T7 to configure a gate electrode of the seventh transistor T7.

As shown in FIG. 7, the gate pattern GE_T8 of the eighth transistor T8 and the gate pattern GE_T9 of the ninth transistor T9 may be formed integrally. However, the disclosure is not limited thereto.

The gate pattern GE_T8 of the eighth transistor T8 may extend in the direction opposite to the first direction DR1, and may overlap a channel area formed in the eighth semiconductor pattern ACT_T8. For example, one end of the gate pattern GE_T8 of the eighth transistor T8 extending in the direction opposite to the first direction DR1 may overlap the channel area formed in the eighth semiconductor pattern ACT_T8 to configure a gate electrode of the eighth transistor T8.

The gate pattern GE_T9 of the ninth transistor T9 may extend in the first direction DR1, and may overlap a channel area formed in the ninth semiconductor pattern ACT_T9. For example, one end of the gate pattern GE_T9 of the ninth transistor T9 extending in the first direction DR1 from the gate pattern GE_T8 of the eighth transistor T8 may overlap the channel area formed in the ninth semiconductor pattern ACT_T9 to configure a gate electrode of the ninth transistor T9.

The fourth sub scan line SL4i may extend in the first direction DR1. The fourth sub scan line SL4i may be formed integrally with the gate pattern GE_T8 of the eighth transistor T8 and the gate pattern GE_T9 of the ninth transistor T9. However, the fourth sub scan line SL4i is not limited the disclosure. Accordingly, referring to FIG. 3E, the gate electrode of the eighth transistor T8 may receive the fourth scan signal GB[i] from the fourth sub scan line SL4i. In addition, the gate electrode of the ninth transistor T9 may receive the fourth scan signal GB[i] from the fourth sub scan line SL4i.

The first conductive layer GAT1 may include one or more metals selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), or copper (Cu). The first conductive layer GAT1 may have a single-layer or multi-layer structure, and for example, the first conductive layer GAT1 may have a single-layer structure including molybdenum (Mo).

Referring to FIGS. 5 to 8, the second conductive layer GAT2 may include a (1_2)-th capacitor electrode C1_E2, a (2_1)-th capacitor electrode C2_E1, a fifth power line PL5a, and a repair line RP. The (1_2)-th capacitor electrode C1_E2 and the (2_1)-th capacitor electrode C2_E1 may be configured integrally, but are not limited thereto.

The (1_2)-th capacitor electrode C1_E2 may overlap the (1_1)-th capacitor electrode C1_E1 and may configure the first capacitor C1 (refer to FIG. 3E) together with the (1_1)-th capacitor electrode C1_E1. The (2_1)-th capacitor electrode C2_E1 may configure one electrode of the second capacitor C2 (refer to FIG. 3E).

The (1_2)-th capacitor electrode C1_E2 and/or the (2_1)-th capacitor electrode C2_E1 may include, or define, a first opening OP1. Accordingly, a fourth bridge pattern BRP4 (to be described later) and the (1_1)-th capacitor electrode C1_E1 or the gate pattern GE_T1 of the first transistor T1 may contact through the first opening OP1. This is described in detail later with reference to FIG. 10.

The fifth power line PL5a may extend in the first direction DR1. The fifth power line PL5a may be connected to one electrode of the ninth transistor T9 through a contact hole. Accordingly, the voltage of the bias power VBS may be supplied to the ninth transistor T9 through the fifth power line PL5a.

The repair line RP may extend in the first direction DR1. The compensation line RP may be connected to each of the plurality of sub-pixels SP (refer to FIG. 1). For example, the compensation line RP may extend in the first direction DR1, and may be connected to the anode electrode of the light-emitting element LD (refer to FIG. 3E) of each of the first sub-pixel SPa, the second sub-pixel SPb, and the third sub-pixel SPc. Accordingly, even if an abnormality occurs (for example, short circuit of a (1_1)-th power line PL1a) on a circuit of one of the plurality of sub-pixels SP (for example, the first sub-pixel SPa), the compensation line RP may apply a voltage (e.g., predetermined voltage) to the anode electrode of the light-emitting element LD of the first sub-pixel SPa to cause the light-emitting element LD of the first sub-pixel SPa to emit light.

Referring to FIGS. 5 to 9, the third conductive layer GAT3 may include a (1_1)-th power line PL1a, a third power line PL3a, and a (2_2)-th capacitor electrode C2_E2. The (1_1)-th power line PL1a and the (2_2)-th capacitor electrode C2_E2 may be configured integrally, but are not limited thereto.

The (1_1)-th power line PL1a may extend in the first direction DR1. The (1_1)-th power line PL1a may overlap the (2_1)-th capacitor electrode C2_E1 and configure the second capacitor C2 (refer to FIG. 3E) together with the (2_1)-th capacitor electrode C2_E1. An area of the (1_1)-th power line PL1a may be greater than an area of the (1_2)-th capacitor electrode C1_E2 and the (2_1)-th capacitor electrode C2_E1, and may cover the (1_2)-th capacitor electrode C1_E2 and the (2_1)-th capacitor electrode C2_E1.

Meanwhile, the (1_1)-th power line PL1a may include/define a second opening OP2 overlapping the first opening OP1. Accordingly, the fourth bridge pattern BRP4 (to be described later) and the (1_1)-th capacitor electrode C1_E1 or the gate pattern GE_T1 of the first transistor T1 may contact through the first opening OP1 and the second opening OP2. This is described in detail later with reference to FIG. 10.

In addition, the (1_1)-th power line PL1a may include/define a third opening OP3. Accordingly, a second bridge pattern BRP2 to be described later and the (2_1)-th capacitor electrode C2_E1 may contact. This is described in detail later with reference to FIG. 10.

The (2_2)-th capacitor electrode C2_E2 may overlap the (2_1)-th capacitor electrode C2_E1, and may configure the second capacitor C2 (refer to FIG. 3E) together with the (2_1)-th capacitor electrode C2_E1.

The third power line PL3a may extend in the first direction DR1. The third power line PL3a may be connected to one electrode of the fourth transistor T4 through a contact hole. Accordingly, the fourth transistor T4 may be supplied with the voltage of the fourth power VINT through the third power line PL3a.

Referring to FIGS. 5 to 10, the fourth conductive layer SD1 may include the first to third sub scan lines SL1i, SL2i, and SL3i, the first and second sub emission control lines EL1i and EL2i, a (2_1)-th power line PL2a, a (4_1)-th power line PL4a, first to fifth bridge patterns BRP1, BRP2, BRP3, BRP4, and BRP5, and a connection electrode CGE.

The first sub scan line SL1i may extend in the first direction DR1. The first sub scan line SL1i may be connected to the gate pattern GE_T2 of the second transistor T2 through a contact hole. At this time, referring also to FIG. 3E, the gate electrode of the second transistor T2 may receive the first scan signal GW[i] from the first sub scan line SL1i. In other words, the gate electrode of the second transistor T2 where the semiconductor pattern ACT_T2 of the second transistor T2 and the gate pattern GE_T2 of the second transistor T2 may contact the first sub scan line SL1i extending in the first direction DR1, and the second transistor T2 may receive the first scan signal GW[i].

The second sub scan line SL2i may extend in the first direction DR1. The second sub scan line SL2i may be connected to the gate pattern GE_T3 of the third transistor T3 through a contact hole, and may be connected to the gate pattern GE_T5 of the fifth transistor T5 through a contact hole. At this time, referring also to FIG. 3E, the gate electrode of the third transistor T3 may receive the second scan signal GC[i] from the second sub scan line SL2i. In other words, the gate electrode of the third transistor T3 where the semiconductor pattern ACT_T3 of the third transistor T3 and the gate pattern GE_T3 of the third transistor T3 overlap may contact the second sub scan line SL2i extending in the first direction DR1, and may be positioned in a lower end portion of the display panel 100, and the third transistor T3 may receive the second scan signal GC[i]. In addition, the gate electrode of the fifth transistor T5 may receive the second scan signal GC[i] from the second sub scan line SL2i. In other words, the gate electrode of the fifth transistor T5, where the semiconductor pattern ACT_T5 of the fifth transistor T5 and the gate pattern GE_T5 of the fifth transistor T5 overlap, may contact the second sub scan line SL2i extending in the first direction DR1, and may be positioned in an upper end portion of the display panel 100, and the fifth transistor T5 may receive the second scan signal GC[i].

The third sub scan line SL3i may extend in the first direction DR1. The third sub scan line SL3i may be connected to the gate pattern GE_T4 of the fourth transistor T4 through a contact hole. At this time, referring also to FIG. 3E, the gate electrode of the fourth transistor T4 may receive the third scan signal GI[i] from the third sub scan line SL3i. In other words, the gate electrode of the fourth transistor T4, where the semiconductor pattern ACT_T4 of the fourth transistor T4 and the gate pattern GE_T4 of the fourth transistor T4 overlap, may contact the third sub scan line SL3i extending in the first direction DR1, and the fourth transistor T4 may receive the third scan signal GI[i].

The first sub emission control line EL1i may extend in the first direction DR1. The first sub emission control line EL1i may be connected to each of the gate pattern GE_T6 of the sixth transistor T6 and the gate pattern GE_T7 of the seventh transistor T7 through a contact hole. At this time, referring also to FIG. 3E, the gate electrode of the sixth transistor T6 may receive the first emission control signal EM1[i] from the first sub emission control line EL1i. In other words, the gate electrode of the sixth transistor T6, where the semiconductor pattern ACT_T6 of the sixth transistor T6 and the gate pattern GE_T6 of the sixth transistor T6, overlap may contact the first sub emission control line EL1i extending in the first direction DR1, and the sixth transistor T6 may receive the first sub emission control signal EM1[i].

In addition, the gate electrode of the seventh transistor T7 may receive the first emission control signal EM1[i] from the first sub emission control line EL1i. In other words, the gate electrode of the seventh transistor T7, where the semiconductor pattern ACT_T7 of the seventh transistor T7 and the gate pattern GE_T7 of the seventh transistor T7 overlap, extends in the first direction DR1. The seventh transistor T7 is in contact with the first sub emission control line EMi and may receive the first emission control signal EM1[i].

The (2_1)-th power line PL2a may extend in the first direction DR1. The (2_1)-th power line PL2a may be connected to one electrode of the fifth transistor T5 through a contact hole.

The (4_1)-th power line PL4a may extend in the first direction DR1. The (4_1)-th power line PL4a may be connected to one electrode of the eighth transistor T8 through a contact hole. Accordingly, the voltage of the anode initialization power VAINT may be supplied to the eighth transistor T8 through the (4_1)-th power line PL4a.

The first bridge pattern BRP1 may overlap one electrode of the second transistor T2, and may contact one electrode of the second transistor T2 through a contact hole. In addition, the first bridge pattern BRP1 may contact the data line DLj formed of the fourth conductive layer SD2 through a contact hole. That is, the first bridge pattern BRP1 may connect one electrode of the second transistor T2 and the data line DLj.

The second bridge pattern BRP2 may extend in the second direction DR2, and may overlap each of a portion of the first semiconductor pattern group ACT1, the (1_2)-th capacitor electrode C1_E2, and the (2_1)-th capacitor electrode C2_E1. The second bridge pattern BRP2 may contact a portion of the first semiconductor pattern group ACT1 through a contact hole, and may be connected to each of one electrode of the second transistor T2 and one electrode of the fifth transistor T5. In addition, the second bridge pattern BRP2 may contact each of the (1_2)-th capacitor electrode C1_E2 and the (2_1)-th capacitor electrode C2_E1 exposed by the third opening OP3 formed in the (1_1)-th power line PL1A. That is, the second bridge pattern BRP2 may configure the third node N3 of FIG. 3E.

The third bridge pattern BRP3 may overlap each of the (1_1)-th power line PL1a and one electrode of the third transistor T3. For example, the third bridge pattern BRP3 may include a (3_1)-th bridge pattern BRP3_1 positioned at a right end of the first sub-pixel SPa and a (3_2)-th bridge pattern BRP3_2 positioned at a left end of the first sub-pixel SPa. At this time, the (3_1)-th bridge pattern BRP3_1 may overlap the (1_1)-th power line PL1a through a contact hole, and the (3_2)-th bridge pattern BRP3_2 may overlap one electrode of the third transistor T3 through a contact hole.

The fourth bridge pattern BRP4 may connect the gate electrode (or the gate pattern GE_T1) of the first transistor T1, the eleventh capacitor electrode C1_E1, the third transistor T3, and one electrode of the fourth transistor T4. For example, one end of the fourth bridge pattern BRP4 may contact the gate pattern GE_T1 of the first transistor T1 through the first opening OP1 of the second conductive layer GAT2 and the second opening OP2 of the third conductive layer GAT3. In addition, another end extending from one end of the fourth bridge pattern BRP4 in the direction opposite to the second direction DR2 may contact the semiconductor pattern ACT_T3 of the third transistor T3 and the semiconductor pattern ACT_T4 of the fourth transistor T4. Accordingly, the fourth bridge pattern BRP4 may connect the gate electrode of the first transistor T1, one electrode of the first capacitor C1, and one electrode of the third transistor T3 and the fourth transistor T4. That is, the fourth bridge pattern BRP4 may configure the first node N1 of FIG. 3E.

The fifth bridge pattern BRP5 may connect one electrode of the seventh transistor T7 and the anode of the light-emitting element LD. For example, the fifth bridge pattern BRP5 may contact the active pattern ACT_T7 of the seventh transistor T7, and may connect the anode of the light-emitting element LD. That is, the fifth bridge pattern BRP5 may configure the fourth node N4 of FIG. 3E.

The connection electrode CGE may extend in the first direction DR1 to overlap the second sub-pixel SPb and the third sub-pixel SPc. The connection electrode CGE may extend in the first direction DR1, and may contact the sixth semiconductor pattern ACT_T6 of each of the second sub-pixel SPb and the third sub-pixel SPc through a contact hole. For example, one end of the connection electrode CGE may contact the sixth semiconductor pattern ACT_T6 of the second sub-pixel SPb, and another end extending from one end of the connection electrode CGE in the first direction DR1 may contact the sixth semiconductor pattern ACT_T6 of the third sub-pixel SPc. At this time, one end of the connection electrode CGE may contact a second portion PL1b″ (see FIG. 11) of the (1_2)-th power line PL1b, and the sixth transistor T6 of the second sub-pixel SPb may receive the voltage of the first power VDD through the connection electrode CGE. Accordingly, the sixth transistor T6 of the third sub-pixel SPc may receive the voltage of the first power VDD through another end of the connection electrode CGE.

Referring to FIGS. 5 to 11, the fifth conductive layer SD2 may include a sixth bridge pattern BRP6, first to third data lines DLj, DLj+1, and DLj+2, a (1_2)-th power line PL1b, a (2_2)-th power line PL2b, and a (4_2)-th power line PL4b.

Referring to FIGS. 10 and 11, the fourth conductive layer SD1 and the fifth conductive layer SD2 may include one or more metals selected from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), or copper (Cu). The fourth conductive layer SD1 and the fifth conductive layer SD2 may have a single-layer or multi-layer structure, and for example, the fourth conductive layer SD1 and the fifth conductive layer SD2 may have a multi-layer structure including Ti/Al/Ti.

The sixth bridge pattern BRP6 may overlap the fifth bridge pattern BRP5, and may contact the fifth bridge pattern BRP5 through a contact hole. The sixth bridge pattern BRP6 may be connected to one electrode of the seventh transistor T7 through the fifth bridge pattern BRP5. In addition, the sixth bridge pattern BRP6 may be connected to the anode of the light-emitting element LD through a contact hole. That is, the sixth bridge pattern BRP6 may connect one electrode of the seventh transistor T7 to the anode of the light-emitting element LD together with the fifth bridge pattern BRP5.

The data line DL may include the first data line DLj, the second data line DLj+1, and the third data line DLj+2, respectively extending in the second direction DR2. The data line DLj may be positioned on one side of each of the sub-pixels SP (refer to FIG. 1) in the first direction DR1. For example, the first data line DLj may be positioned on one side of the first sub-pixel area SPAa in the first direction DR1, and may overlap the first bridge pattern BRP1. The first data line DLj may contact the first bridge pattern BRP1 through a contact hole, and may be connected to one electrode of the second transistor T2 through the first bridge pattern BRP1.

The (1_2)-th power line PL1b may be positioned on another side of each of the sub-pixels SP in the first direction DR1. The (1_2)-th power line PL1b may include a first portion PL1b′ of the (1_2)-th power line overlapping the first sub-pixel SPa and a second portion PL1b″ of the (1_2)-th power line overlapping the second sub-pixel SPb. The (1_2)-th power line PL1b may be connected to the (1_1)-th power line PL1a through the third bridge pattern BRP3 and a contact hole.

The (2_2)-th power line PL2b may extend in the second direction DR2, and may be positioned on another side of the third sub-pixel SPc in the first direction DR1. The (2_2)-th power line PL2b may overlap the (2_1)-th power line PL2a. The (2_2)-th power line PL2b may contact the (2_1)-th power line PL2a through a contact hole, and may be connected to one electrode of the fifth transistor T5 through a contact hole. Accordingly, the fifth transistor T5 may receive the voltage of the third power VREF (or reference power). In FIGS. 5 and 11, the (2_2)-th power line PL2b may overlap the third sub-pixel SPc or the pixel circuit SPC of the third sub-pixel SPc, but the disclosure is not limited thereto. For example, the (2_2)-th power line PL2b may overlap the first sub-pixel SPa or the second sub-pixel SPb. In addition, the (2_2)-th power line PL2b may alternately overlap the first sub-pixel SPa and the third sub-pixel SPc.

According to one or more embodiments of the disclosure, the number of lines of the fifth conductive layer SD2 extending in one direction (for example, the second direction DR2) may be relatively small. A resistance of the fifth conductive layer SD2 may not be relatively great. For example, as shown in FIG. 11, the third sub-pixel SPc may include the (2_2)-th power line PL2b extending in the second direction DR2 differently from the first sub-pixel SPa or the second sub-pixel SPb. In other words, the third sub-pixel SPc may have a structure in which the (1_2)-th power line PL1b of the first sub-pixel SPa or the second sub-pixel SPb is replaced with the (2_2)-th power line PL2b.

In a comparative example, when each of the plurality of sub-pixels SPa, SPb, and SPc overlaps the portions PL1b′ and PL1b″ of the (1_2)-th power line PL1b extending in the second direction DR2, and when each of the sub-pixels SPa, SPb, and SPc overlaps a plurality of (2_2)-th power lines PL2b, a width of each of the (1_2)-th power lines PL1b and the (2_2)-th power lines PL2b becomes relatively very narrow. Accordingly, a resistance of the fifth conductive layer SD2 configuring each of the (1_2)-th power lines PL1b and the (2_2)-th power lines PL2b may relatively increase. In this comparative example, a problem may occur in which power consumption due to heat generation increases.

However, in the display panel 100 according to one or more embodiments of the disclosure, one pixel may overlap only the first portion PL1b′ and the second portion PL1b″ of the (1_2)-th power line PL1b extending in the second direction DR2, and one (2_2)-th power line PL2b. Accordingly, the number of lines configured of the fifth conductive layer SD2 may be reduced, and the resistance of the fifth conductive layer SD2 configuring each of the (1_2)-th power line PL1b and the (2_2)-th power line PL2b may be reduced. According to this, when the display panel 100 (or the display device 1000) including the fifth conductive layer SD2 is driven, power consumption due to heat generation may be relatively reduced.

Resistances of one of the (1_2)-th power lines PL1b or the (2_2)-th power line PL2b may be substantially the same. For example, resistances of the (2_2)-th power line PL2b and the second portion PL1b″ of the (1_2)-th power line PL1b, each being configured of the fifth conductive layer SD2, may be substantially the same.

The (1_1)-th power line PL1a and the (1_2)-th power line PL1b may form a mesh structure. In addition, the (2_1)-th power line PL2a and the (2_2)-th power line PL2b may form a mesh structure. Accordingly, when driving the display device 1000, a voltage drop (for example, IR drop) may occur relatively less, and a spot dispersion of the display panel 100 may be reduced.

The (4_2)-th power line PL4b may extend in the second direction DR2. For example, the (4_2)-th power line PL4b may be located between the first sub-pixel SPa and the second sub-pixel SPb, and may extend in the second direction DR2. The (4_2)-th power line PL4b may be connected to the eighth transistor T8. For example, a portion of the (4_2)-th power line PL4b configured of the fifth conductive layer SD2 may contact the (4_1)-th power line PL4a configured of the fourth conductive layer SD1. At this time, the (4_2)-th power line PL4b may be connected to the eighth transistor T8 via the (4_1)-th power line PL4a. Accordingly, the voltage of the fifth power VAINT may be supplied to one electrode of the eighth transistor T8. However, the voltage supplied through the (4_2)-th power line PL4b is not limited thereto. For example, according to one or more embodiments, the voltages of the third power VREF, the fourth power VINT, and the sixth power VBS may be applied to the (4_2)-th power line PL4b.

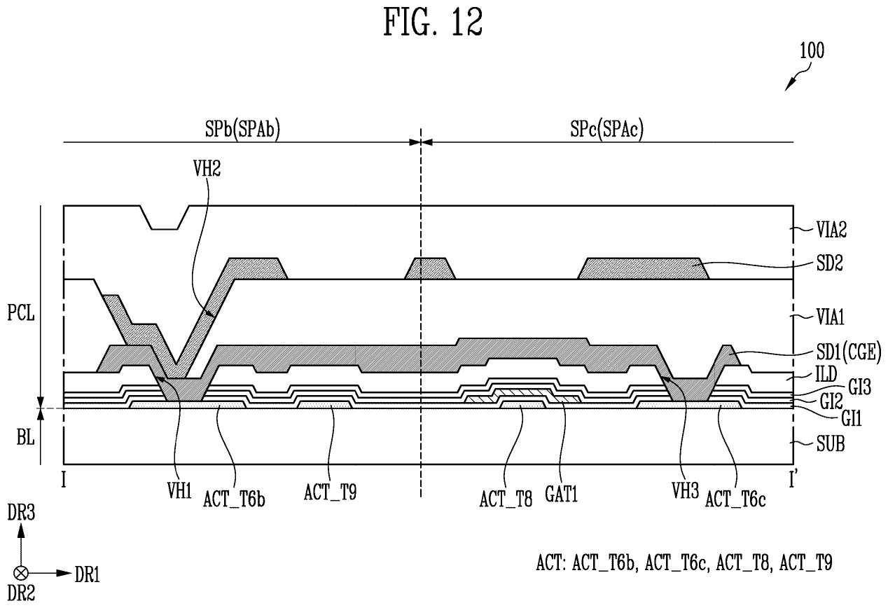

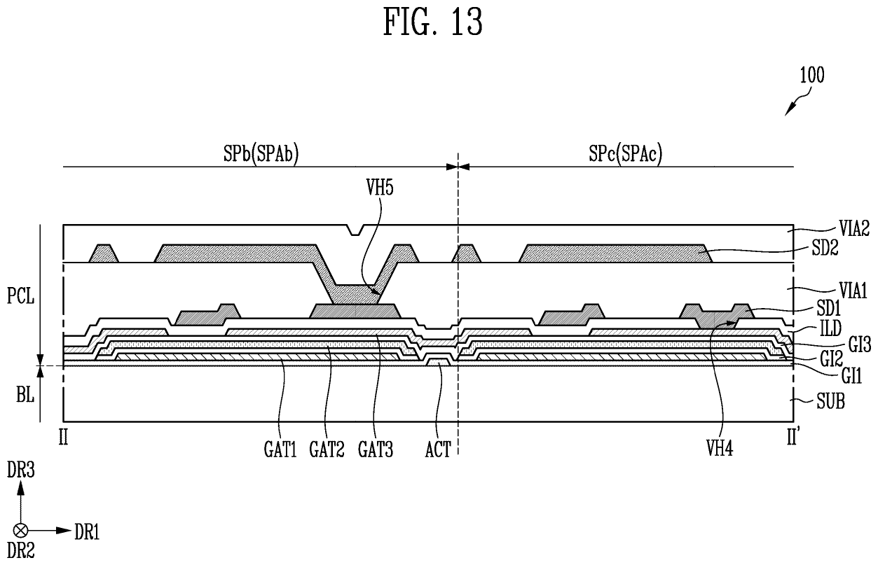

FIG. 12 is a cross-sectional view illustrating a stack structure of the display panel along the line I-I′ of FIG. 5. FIG. 13 is a cross-sectional view illustrating the stack structure of the display panel along the line II-II′ of FIG. 5.

Referring to FIGS. 12 and 13, the display panel 100 may include a base layer BL and a pixel circuit layer PCL. In one or more embodiments, the display panel 100 may further include a display element layer, an encapsulation layer, an optical layer, and/or the like positioned on/above the pixel circuit layer PCL. However, embodiments of the disclosure are not limited thereto.

For example, the display element layer may be located on the pixel circuit layer PCL (as used herein, “located on” may mean “above”). The display element layer may include the anode AE (refer to FIG. 2), the cathode CE (refer to FIG. 2), a light-emitting layer, and the like.

The base layer BL may be a base substrate or base member for supporting the display device 1000. The base layer BL may include a substrate SUB. The substrate SUB may be a rigid substrate of a glass material. In addition, the substrate SUB may be a flexible substrate capable of bending, folding, rolling, or the like. In this case, the substrate SUB may include an insulating material, such as a polymer resin (e.g., polyimide).

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, or a semiconductor on insulator (SeOl) layer. In other embodiments, the substrate SUB may include a glass substrate.

The pixel circuit layer PCL is located on the substrate SUB. The substrate SUB and/or the pixel circuit layer PCL may include insulating layers, and conductive patterns located between the insulating layers. The conductive patterns of the pixel circuit layer PCL may function as at least a portion of circuit elements, lines, and the like. The conductive patterns may include copper, but embodiments are not limited thereto.

According to one or more embodiments, the base layer BL may further include a barrier layer, a buffer layer, and the like. The barrier layer may be configured between the substrate SUB and the pixel circuit layer PCL to block an unnecessary or unwanted component, such as moisture or oxygen, from entering the light-emitting element LD (refer to FIG. 3E) from an outside. The buffer layer may be configured to reduce or prevent the likelihood of an impurity ion diffusing, and to reduce or prevent penetration of moisture or external air.

The pixel circuit layer PCL may include a semiconductor layer ACT, a first insulating layer GI1 (or a first gate insulating layer), a first conductive layer GAT1, a second insulating layer GI2 (or a second gate insulating layer), a second conductive layer GAT2, a third insulating layer GI3 (or a third gate insulating layer), a third conductive layer GAT3, an interlayer insulating layer ILD, a fourth conductive layer SD1, a first via layer VIA1, a fifth conductive layer SD2, and a second via layer VIA2 sequentially stacked on the base layer BL. The semiconductor layer ACT, the first conductive layer GAT1, the second conductive layer GAT2, the third conductive layer GAT3, the fourth conductive layer SD1, and the fifth conductive layer SD2 of FIGS. 12 and 13 may be described similarly to the semiconductor layer ACT, the first conductive layer GAT1, the second conductive layer GAT2, the third conductive layer GAT3, the fourth conductive layer SD1, and the fifth conductive layer SD2 of FIGS. 5 to 11. Hereinafter, an overlapping description is omitted.

Referring to FIGS. 5, 6, and 12, the semiconductor layer ACT may be located on the base layer BL. For example, the semiconductor layer ACT may be located between the substrate SUB and the first insulating layer GI1. The semiconductor layer ACT may include a sixth semiconductor pattern ACT_T6b configuring the sixth transistor T6 of the second sub-pixel SPb and a ninth semiconductor pattern ACT_T9 configuring the ninth transistor T9. In addition, the semiconductor layer ACT may include a sixth semiconductor pattern ACT_T6c configuring the sixth transistor T6 of the third sub-pixel SPc and an eighth semiconductor pattern ACT_T8 configuring the eighth transistor T8.

The first insulating layer GI1 may be located on the semiconductor layer ACT. The first insulating layer GI1 may be an inorganic insulating layer including an inorganic material. According to one or more embodiments, the first insulating layer GI1 may be formed of an organic insulating layer including an organic material. The first insulating layer GI1 may be provided as a single layer, but may also be provided as a multilayer of at least two or more layers.

Referring to FIGS. 7 and 12, the first conductive layer GAT1 may be located on the first insulating layer GI1. The first conductive layer GAT1 may include a gate pattern GE_T8 of the eighth transistor T8.

The second insulating layer GI2 may be located on the first insulating layer GI1 and the first conductive layer GAT1. The second insulating layer GI2 may be located substantially over the entire surface of the substrate SUB. The second insulating layer GI2 may include the same material as the first insulating layer GI1, but is not limited thereto.

The third insulating layer GI3 may be located on the second insulating layer GI2. The third insulating layer GI3 may be located substantially over the entire surface of the substrate SUB. The third insulating layer GI3 may include the same material as the first insulating layer GI1, but is not limited thereto.

The interlayer insulating layer ILD may be located on the third insulating layer GI3. The interlayer insulating layer ILD may be an inorganic insulating layer including an inorganic material. According to one or more embodiments, the interlayer insulating layer ILD may be formed of an organic insulating layer including an organic material.

The interlayer insulating layer ILD may include a first via hole VH1 and a third via hole VH3. The first via hole VH1 and the third via hole VH3 may pass through the first insulating layer GI1, the second insulating layer GI2, and the third insulating layer GI3. For example, the first via hole VH1 and the third via hole VH3 may expose the semiconductor layer ACT in the third direction DR3. Accordingly, the fourth conductive layer SD1 may contact the sixth semiconductor pattern ACT_T6b configuring the sixth transistor T6 of the second sub-pixel SPb through the first via hole VH1. In addition, the fourth conductive layer SD1 may contact the sixth semiconductor pattern ACT_T6c configuring the sixth transistor T6 of the third sub-pixel SPc through the third via hole VH3.

Referring to FIGS. 10 and 12, the fourth conductive layer SD1 may be located on the interlayer insulating layer ILD. The fourth conductive layer SD1 may include a connection electrode CGE. For example, the fourth conductive layer SD1 may include the connection electrode CGE extending in the first direction DR1, and contacting the semiconductor layer ACT through the first via hole VH1 and the third via hole VH3. The connection electrode CGE may connect the sixth semiconductor pattern ACT_T6b of the second sub-pixel SPb and the sixth semiconductor pattern ACT_T6c of the third sub-pixel SPc.

The first via layer VIA1 may be located on the interlayer insulating layer ILD and the fourth conductive layer SD1. The first via layer VIA1 may be located substantially over the entire surface of the substrate SUB.

The first via layer VIA1 may include an organic insulating material, such as acrylic resin, epoxy resin, phenol resin, polyamide resin, polyimide resin, unsaturated polyester resin, polyphenylene ether resin, polyphenylene sulfide resin, or benzocyclobutene (BCB), but is not limited thereto.

The first via layer VIA1 may include a second via hole VH2. For example, the first via layer VIA1 may include the second via hole VH2 allowing the fifth conductive layer SD2 and the fourth conductive layer SD1 to be in contact with each other.

Referring to FIGS. 11 and 12, the fifth conductive layer SD2 may be located on the first via layer VIA1. The fifth conductive layer SD2 may include the second portion PL1b″ of the (1_2)-th power line, the third data line DLj+2, and the (2_2)-th power line PL2b.

Meanwhile, the first via layer VIA1 may not expose the fourth conductive layer SD1 configuring the sixth transistor T6 of the third sub-pixel SPc. Accordingly, the fourth conductive layer SD1 configuring the sixth transistor T6 of the third sub-pixel SPc may not contact the fifth conductive layer SD2. At this time, the second part PL1b″ of the (1_2)-th power line configured of the fifth conductive layer SD2 may contact the connection electrode CGE configured of the fourth conductive layer SD1 through the second via hole VH2. Accordingly, the sixth transistor T6 of the third sub-pixel SPc may be connected to the sixth transistor of the second sub-pixel SPb through the connection electrode CGE. The sixth transistor T6 of the second sub-pixel SPb may be connected to the fifth conductive layer SD2. Accordingly, the sixth transistor T6 of the second sub-pixel SPb and the sixth transistor T6 of the third sub-pixel SPC may receive the voltage of the first power VDD through the connection electrode CGE.

According to one or more embodiments of the disclosure, the third sub-pixel SPc may extend in the second direction DR2, and may not include a line to which the voltage of the first power VDD is applied, but the third sub-pixel SPc (or the sixth transistor T6 of the third sub-pixel SPc) may receive the voltage of the first power VDD through the connection electrode CGE.

The second via layer VIA2 may be located on the fifth conductive layer SD2. The second via layer VIA2 may be located substantially over the entire surface of the substrate SUB. The second via layer VIA2 may include the same material as the first via layer VIA1, but is not limited thereto.

Referring to FIGS. 6 and 13, the semiconductor layer ACT may be located on the base layer BL. The semiconductor layer ACT may include the first semiconductor pattern ACT_T1 configuring the first transistor T1.

Referring to FIGS. 7 and 13, the first conductive layer GAT1 may be located on the first insulating layer GI1. The first conductive layer GAT1 may include the eleventh capacitor electrode C1_E1 of the second sub-pixel SPb and the third sub-pixel SPc.

Referring to FIGS. 8 and 13, the second conductive layer GAT2 may be located on the second insulating layer GI2. The second conductive layer GAT2 may include a twelfth capacitor electrode C1_E2 and/or a twenty-first capacitor electrode C2_E1.

Referring to FIGS. 9 and 13, the third conductive layer GAT3 may be located on the third insulating layer GI3. The third conductive layer GAT3 may include a twenty-second capacitor electrode C2_E2.

The interlayer insulating layer ILD may be located on the third conductive layer GAT3. The interlayer insulating layer ILD may include a fourth via hole VH4. For example, the interlayer insulating layer ILD may include the fourth via hole VH4 exposing the third conductive layer GAT3 overlapping the third sub-pixel SPc in the third direction DR3.

Referring to FIGS. 10 and 13, the fourth conductive layer SD1 may be located on the interlayer insulating layer ILD. The fourth conductive layer SD1 may include a second bridge pattern BRP2 and a (3_1)-th bridge pattern BRP3_1.

According to one or more embodiments of the disclosure, the fourth conductive layer SD1 overlapping the third sub-pixel SPc may contact the third conductive layer GAT3 overlapping the third sub-pixel SPc. For example, the (3_1)-th bridge pattern BRP3_1 of the fourth conductive layer SD1 positioned in the third sub-pixel area SPAc may contact the third conductive layer GAT3 positioned in the third sub-pixel area SPAc.

The first via layer VIA1 may be located on the fourth conductive layer SD1 and the interlayer insulating layer ILD. The first via layer VIA1 may include a fifth via hole VH5 exposing the fourth conductive layer SD1. For example, the first via layer VIA1 may expose the (3_1)-th bridge pattern BRP3_1 of the fourth conductive layer SD1 overlapping the second sub-pixel SPb.

According to one or more embodiments of the disclosure, the fifth conductive layer SD2 positioned on the third sub-pixel area SPAc may contact the fourth conductive layer SD1 positioned on the second sub-pixel area SPAc through the fifth via hole VH5. For example, the second portion PL1b″ of the (1_2)-th power line PL1b configured of the fifth conductive layer SD2 may contact the (3_1)-th bridge pattern BRP3_1 configured of the third conductive layer GAT3 through the fifth via hole VH5.

The second via layer VIA2 may be located on the second interlayer insulating layer ILD2 and the fifth conductive layer SD2. The second via layer VIA2 may be located substantially over the entire surface of the substrate SUB. The second via layer VIA2 may include the same material as the first via layer VIA1, but is not limited thereto.

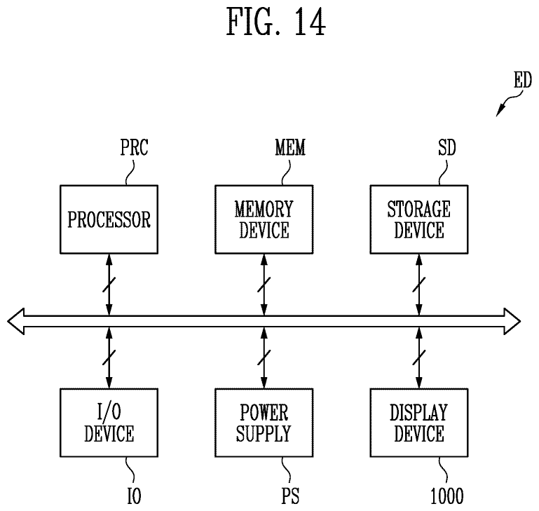

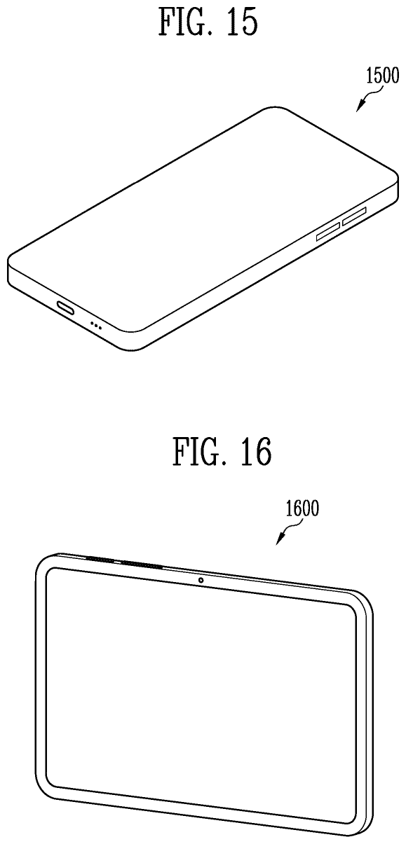

FIG. 14 is a block diagram illustrating an electronic device including a display device according to embodiments of the disclosure. FIG. 15 is a perspective view illustrating an example in which the electronic device of FIG. 14 is implemented as a smartphone. FIG. 16 is a perspective view illustrating an example in which the electronic device of FIG. 14 is implemented as a tablet PC.

Referring to FIGS. 14 to 16, the electronic device ED may include a processor PRC, a memory device MEM, a storage device SD, an input/output device IO, a power supply PS, and a display device 1000. At this time, the display device 1000 may be the display device of FIG. 1. In addition, the electronic device ED may further include several ports capable of communicating with a video card, a sound card, a memory card, a USB device, or the like, or capable of communicating with other systems. In one or more embodiments, as shown in FIG. 15, the electronic device ED may be implemented as a smart phone. In one or more other embodiments, as shown in FIG. 16, the electronic device ED may be implemented as a tablet PC. However, this is only an example, and the electronic device ED is not limited thereto. For example, the electronic device ED may be implemented as a mobile phone, a video phone, a smart pad, a smart watch, a vehicle navigation device, a computer monitor, a notebook computer, a head mounted display device, or the like.

The processor PRC may perform corresponding calculations or tasks. According to one or more embodiments, the processor PRC may be a microprocessor, a central processing unit, an application processor, or the like. The processor PRC may be connected to other components through an address bus, a control bus, a data bus, or the like. According to one or more embodiments, the processor PRC may also be connected to an expansion bus, such as a peripheral component interconnect (PCI) bus.

The memory device MEM may store data suitable for an operation of the electronic device ED. For example, the memory device MEM may include a non-volatile memory device, such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), and a ferroelectric random access memory (FRAM) device, a volatile memory device, such as a dynamic random access memory (DRAM) device, a static random access memory (SRAM) device, and a mobile DRAM device, and/or the like.

The storage device SD may include a solid state drive (SSD), a hard disk drive (HDD), a compact disc read only memory, and the like.

The input/output device IO may include an input means, such as a keyboard, a keypad, a touch pad, a touch screen, and a mouse, and an output means, such as a speaker and a printer. According to one or more embodiments, the display device 1000 may be included in the input/output device IO.

The power supply PS may supply power suitable for an operation of the electronic device ED. For example, the power supply PS may be a power management integrated circuit (PMIC).

The display device 1000 may display an image corresponding to visual information of the electronic device ED. At this time, the display device 1000 may be an organic light-emitting display device or a quantum dot light-emitting display device, but is not limited thereto. The display device 1000 may be connected to other components through the buses or other communication links.

Referring to FIG. 15, power consumption of the smartphone 1500 including the display device according to embodiments of the disclosure may be reduced.

Referring to FIG. 16, power consumption of the tablet PC 1600 including the display device according to embodiments of the disclosure may be reduced.

Although embodiments and application examples are described herein, other embodiments and modifications may be derived from the above description. Therefore, the spirit of the disclosure is not limited to such embodiments, and extends to the scope of the claims set forth below, various obvious modifications, and equivalents.

What is claimed is:

1. A display device comprising:
a first sub-pixel comprising a first pixel circuit;
a second sub-pixel comprising a second pixel circuit, and extending in a first direction from the first sub-pixel;
a (1_2)-th power line overlapping the first pixel circuit, and extending in a second direction crossing the first direction;
a (2_2)-th power line overlapping the second pixel circuit, and extending in the second direction;
a (1_1)-th power line connecting the (1_2)-th power line and the second sub-pixel, and extending in the first direction; and
a (2_1)-th power line connecting the (2_2)-th power line and the first sub-pixel, and extending in the first direction.

2. The display device according to claim 1, further comprising:
a first data line overlapping the first pixel circuit, and extending in the second direction; and
a second data line overlapping the second pixel circuit, and extending in the second direction,
wherein the (1_2)-th power line is between the first data line and the second data line.

3. The display device according to claim 2, wherein the second data line is between the (1_2)-th power line and the (2_2)-th power line.

4. The display device according to claim 1, wherein a resistance of the (1_2)-th power line and a resistance of the (2_2)-th power line are substantially equal.

5. The display device according to claim 1, further comprising:
a base layer;
a semiconductor layer above the base layer;
an interlayer insulating layer above the semiconductor layer, and defining a first via hole exposing at least a portion of the semiconductor layer overlapping the first pixel circuit;
a first conductive layer above the interlayer insulating layer;
a via layer above the first conductive layer, and defining a second via hole exposing at least a portion of the first conductive layer overlapping the first pixel circuit; and
a second conductive layer above the via layer.

6. The display device according to claim 5, wherein the via layer does not expose the first conductive layer overlapping the second pixel circuit.

7. The display device according to claim 6, wherein the (1_2)-th power line of the second conductive layer overlaps the first pixel circuit,
wherein the (1_2)-th power line contacts a connection electrode of the first conductive layer through the second via hole, and
wherein the connection electrode contacts the first pixel circuit comprising the semiconductor layer through the first via hole.

8. The display device according to claim 7, wherein the interlayer insulating layer defines a third via hole exposing at least a portion of the semiconductor layer overlapping the second pixel circuit,
wherein the connection electrode extends in the first direction from the first pixel circuit to an area overlapping the second pixel circuit, and
wherein the connection electrode contacts the second pixel circuit comprising an active layer through the third via hole on the second pixel circuit.

9. The display device according to claim 5, further comprising a gate layer between the semiconductor layer and the interlayer insulating layer,
wherein the interlayer insulating layer defines a fourth via hole exposing at least a portion of the gate layer overlapping the second pixel circuit.

10. The display device according to claim 9, wherein the via layer defines a fifth via hole exposing at least a portion of a fourth conductive layer overlapping the first pixel circuit.

11. The display device according to claim 2, wherein the first sub-pixel and the second sub-pixel comprise:
a light-emitting element;
a driving transistor connected between the (1_1)-th power line and a second node for controlling a driving current supplied to the light-emitting element in response to a voltage of a first node connected to a first gate electrode;
a first capacitor comprising one electrode connected to the first node, and another electrode connected to a third node;
a second transistor connected between the third node and the first data line or the second data line, and configured to be turned on by a first scan signal;
a third transistor connected between the first node and the second node, and configured to be turned on by a second scan signal;
a fourth transistor connected between the first node and initialization power, and configured to be turned on by a third scan signal; and
a fifth transistor connected between the (2_1)-th power line and the third node, and configured to be turned on by the second scan signal.

12. The display device according to claim 11, further comprising:
a sixth transistor connected between the second node and a fourth node connected to one electrode of the light-emitting element, and configured to be turned on by a first emission control signal;
a seventh transistor connected between the fourth node and an anode initialization power line, and configured to be turned on by a fourth scan signal; and
a second capacitor comprising one electrode connected to the (1_1)-th power line and another electrode connected to the third node.

13. The display device according to claim 11, further comprising:
a sixth transistor connected between the (1_1)-th power line and a fifth node connected to one electrode of the driving transistor, and configured to be turned on by a first emission control signal;
a seventh transistor connected between the second node and a fourth node connected to one electrode of the light-emitting element, and configured to be turned on by a second emission control signal;
an eighth transistor connected between the fourth node and an anode initialization power, and configured to be turned on by a fourth scan signal; and
a ninth transistor connected between the fifth node and a bias power, and configured to be turned on by the fourth scan signal.

14. The display device according to claim 13, wherein the driving transistor and the second to ninth transistors comprise P-type transistors.

15. The display device according to claim 13, wherein the second transistor, the third transistor, the fourth transistor, and the fifth transistor comprise N-type transistors, and
wherein the driving transistor, the sixth transistor, the seventh transistor, the eighth transistor, and the ninth transistor comprise P-type transistors.

16. The display device according to claim 13, further comprising a tenth transistor connected between the (1_1)-th power line and the fifth node, and configured to be turned on by the second scan signal.

17. The display device according to claim 2, wherein the first sub-pixel and the second sub-pixel comprise:
a light-emitting element;
a driving transistor connected between a second node and a fifth node for controlling a driving current supplied to the light-emitting element in response to a voltage of a first node connected to a first gate electrode;
a second transistor connected between a third node and the first data line or the second data line, and configured to be turned on by a first scan signal;
a first capacitor comprising one electrode connected to the third node, and another electrode connected to the first node;
a third transistor connected between the first node and the second node connected to one electrode of the driving transistor, and configured to be turned on by a second scan signal;
a fourth transistor connected between the third node and the (2_1)-th power line, and configured to be turned on by the second scan signal; and
a fifth transistor connected between the (1_1)-th power line and the fifth node, and configured to be turned on by a first emission control signal.

18. The display device according to claim 17, further comprising:
a second capacitor comprising one electrode connected to the (1_1)-th power line, and another electrode connected to the third node;
a sixth transistor connected between the second node and a fourth node connected to one electrode of the light-emitting element, and configured to be turned on by a second emission control signal;
a seventh transistor connected between the fourth node and an anode initialization power line, and configured to be turned on by the first emission control signal; and
an eighth transistor connected between the fifth node and a bias power, and configured to be turned on by the first scan signal.

19. An electronic device comprising:
a processor configured to provide input image data; and
a display device configured to display an image based on the input image data, and comprising:
a first sub-pixel comprising a first pixel circuit;
a second sub-pixel comprising a second pixel circuit spaced apart from the first sub-pixel in a first direction;
a (1_2)-th power line overlapping the first pixel circuit, and extending in a second direction crossing the first direction;
a (2_2)-th power line overlapping the second pixel circuit, and extending in the second direction;
a (1_1)-th power line connecting the (1_2)-th power line and the second sub-pixel, and extending in the first direction; and
a (2_1)-th power line connecting the (2_2)-th power line and the first sub-pixel, and extending in the first direction.

20. The electronic device according to claim 19, further comprising:
a first data line overlapping the first pixel circuit, and extending in the second direction; and
a second data line overlapping the second pixel circuit, and extending in the second direction,
wherein the (1_2)-th power line is between the first data line and the second data line.
